(19) United States
(12) Patent Application Publication
(10) Pub. No.: US 2006/0033537 A1
(43) Pub. Date: Feb. 16, 2006

(54) Semiconductor device, printed-circuit board and electronics device

(75) Inventors: Hidenobu Ito, Kasugai (JP); Hidekiyo Ozawa, Kasugai (JP)

Correspondence Address: ARENT FOX PLLC, 1050 CONNECTICUT AVENUE, N.W., SUITE 400, WASHINGTON, DC, 20036, US

(73) Assignee: FUJITSU LIMITED

(21) Appl. No.: 11/092,770

(22) Filed: Mar. 30, 2005

(30) Foreign Application Priority Data
Aug. 16, 2004 (JP) 2004-236537

(51) Int. Cl. H03B 1/00

(52) U.S. Cl. 327/110

(57) ABSTRACT

A first terminal receives an input voltage. A second terminal is connected to one end of an inductor element. A third terminal is connected to the other end of the inductor element. For example, the third terminal (the other end of the inductor element) is connected to a ground line via a capacitor element. A switch circuit connects the second terminal to one of the first terminal and a ground line. A control circuit switches a connection destination of the switch circuit according to a voltage of the third terminal in order to set the third terminal at a predetermined voltage. An internal circuit receives the voltage of the third terminal as a power supply voltage.

### CROSS REFERENCE TO RELATED APPLICATION

This application is based upon and claims the benefit of priority from Japanese Patent Application No. 2004-236537, filed on Aug. 16, 2004, the entire contents of which are incorporated herein by reference.

### BACKGROUND OF THE INVENTION

1. Field of the Invention

The present invention relates to a semiconductor device, a printed-circuit board and an electronics device, and more particularly, to a semiconductor device having an internal power supply circuit, a printed-circuit board with the semiconductor device mounted thereon, and an electronics device including the semiconductor device.

2. Description of the Related Art

In an electronics device (such as a cellular phone) including various semiconductor devices, it is necessary to prepare a plurality of power supply voltages if power-supply voltages of semiconductor devices (for example, semiconductor devices mounted on a printed-circuit board in the electronics device) are different from one another. Mounting a plurality of power supply circuits tailored to all the semiconductor devices in the electronics device has great disadvantages such as increase in scale and in manufacturing cost of the electronics device. Therefore, generally, several kinds of general-purpose power supply circuits are mounted in the electronics device and semiconductor devices each designed to suit one of the power supply voltages of the general-purpose power supply circuits are mounted. As a result, an enormous number of man-hours are required to achieve both higher speed of the semiconductor devices and securing of an operation margin for the power supply voltages.

In order to solve this problem, in some known semiconductor device, a built-in internal power-supply circuit constituted of a linear regulator steps down an input voltage from an external power supply circuit and a resultant voltage is used as a power supply voltage. In the linear regulator, a resistance value of a variable resistor element is adjusted so that an output voltage is constantly kept at a predetermined voltage value. Further, Japanese Unexamined Patent Application Publication Nos. Hei 8-340669, 2000-92824, and 2002-83872 disclose techniques relating to a switching regulator capable of generating an output voltage more efficiently than a linear regulator.

### SUMMARY OF THE INVENTION

It is an object of the present invention to provide a semiconductor device which can prevent heat generation from an internal power supply circuit and does not take any designing restriction from an input voltage from an external power supply circuit as well as a printed-circuit board with the semiconductor device mounted thereon and an electronics device including the semiconductor device. It is another object of the present invention to generate, by the internal power supply circuit, not only a voltage that is lower than an input voltage but also a voltage that is higher than the input voltage or a negative voltage.

According to a first aspect of the present invention, a semiconductor device is, for example, mounted on a printed-circuit board or mounted in an electronics device. A first terminal receives an input voltage. A second terminal is connected to one end of an inductor element. A third terminal is connected to the other end of the inductor element. A switch circuit connects the second terminal to one of the first terminal and a ground line. A control circuit switches a connection destination of the switch circuit according to a voltage of the third terminal in order to set the third terminal at a predetermined voltage. An internal circuit receives the voltage of the third terminal as a power supply voltage.

In the semiconductor device as structured above, while the switch circuit is connecting the second terminal to the first terminal, a current IL flowing through the inductor element increases with time and it is represented by the following expression (1) where an Vi is an input voltage, Vo is a voltage of the third terminal, L is an inductance of the inductor element, and T1 is a period in which the second terminal is connected to the first terminal by the switch circuit.
IL=(Vi−Vo)/L×T1 (1)

On the other hand, while the switch circuit is connecting the second terminal to the ground line, the current IL flowing through the inductor element decreases with time, and is represented by the following expression (2) where Vo is the voltage of the third terminal, L is the inductance of the inductor element, and T2 is a period in which the second terminal is connected to the ground line by the switch circuit.
IL=Vo/L×T2 (2)

The currents IL flowing through the inductor element obtained by the expression (1) and the expression (2) are the same, and thus the voltage Vo of the third terminal is represented by the following expression (3) which is transformed from the expressions (1), (2).
Vo=T1/(T1+T2)×Vi (3)

Therefore, the third terminal can be set at a predetermined voltage that is lower than the input voltage by the control circuit controlling a ratio of the connection period of the second terminal to the first terminal by the switch circuit and the connection period of the second terminal to the ground line by the switch circuit. Consequently, the internal circuit can constantly receive the voltage that is lower than the input voltage as the power supply voltage. As a result, the internal circuit can be designed, being free from any restriction by the input voltage from an external power supply circuit. Further, since the switch circuit does not consume power by heat generation unlike a variable resistor element of a linear regulator, it is not necessary to consider heat generation of an internal power supply circuit in designing the internal circuit, and a heat release capability of a package does not restrict a permissible amount of heat generated by the internal circuit. This can contribute to improvement in function and speed of the semiconductor device.

In a preferable example of the first aspect of the present invention, a first switch of the switch circuit connects the second terminal to the first terminal. A second switch of the switch circuit connects the second terminal to the ground line. This can facilitate designing the switch circuit.

According to a second aspect of the present invention, a semiconductor device is, for example, mounted on a printed-circuit board or mounted in an electronics device. A first terminal receives an input voltage. A second terminal is connected to one end of an inductor element receiving the input voltage at the other end. A switch circuit connects the second terminal to one of a third terminal and a ground line. A control circuit switches a connection destination of the switch circuit according to a voltage of the third terminal in order to set the third terminal at a predetermined voltage. An internal circuit receives the voltage of the third terminal as a power supply voltage.

In the semiconductor device as structured above, while the switch circuit is connecting the second terminal to the ground line, a current IL flowing through the inductor element increases with time, and is represented by the following expression (4) where Vi is an input voltage, L is an inductance of the inductor element, and T1 is a period in which the second terminal is connected to the ground line by the switch circuit.
IL=Vi/L×T1 (4)

On the other hand, while the switch circuit is connecting the second terminal to the third terminal, the current IL flowing through the inductor element decreases with time, and is represented by the following expression (5) where Vo is a voltage of the third terminal, Vi is the input voltage, L is the inductance of the inductor element, and T2 is a period T2 in which the second terminal is connected to the third terminal by the switch circuit.
IL=(Vi−Vo)/L×T2 (5)

The currents IL flowing through the inductor element obtained by the expression (4) and the expression (5) are the same, and thus the voltage Vo of the third terminal is represented by the following expression (6) which is transformed from the expressions (4), (5).
Vo=(T1+T2)/T2×Vi (6)

Therefore, the third terminal can be set at a predetermined voltage higher than the input voltage by the control circuit controlling a ratio of the period in which the switch circuit connects the second terminal to the third terminal to the period in which the switch circuit connects the second terminal to the ground line. Consequently, the internal circuit can constantly receive the voltage that is higher than the input voltage as the power supply voltage. As a result, the internal circuit can be designed, being free from any restriction by the input voltage from an external power supply circuit. Further, since the switch circuit does not consume power by heat generation unlike a variable resistor element of a linear regulator, it is not necessary to consider heat generation of an internal power supply circuit in designing the internal circuit, and a heat release capability of a package does not limit a permissible amount of heat generated by the internal circuit. This can contribute to improvement in function and speed of the semiconductor device.

In a preferable example of the second aspect of the present invention, a first switch of the switch circuit connects the second terminal to the third terminal. A second switch of the switch circuit connects the second terminal to the ground line. This can facilitate designing of the switch circuit.

According to a third aspect of the present invention, a semiconductor device is, for example, mounted on a printed-circuit board or mounted in an electronics device. A first terminal receives an input voltage. A second terminal is connected to a ground line via an inductor element. A switch circuit connects the second terminal to one of the first terminal and a third terminal. A control circuit switches a connection destination of the switch circuit according to a voltage of the third terminal in order to set the third terminal at a predetermined voltage. An internal circuit receives the voltage of the third terminal as a power supply voltage.

In the semiconductor device as structured above, while the switch circuit is connecting the second terminal to the first terminal, a current IL flowing through the inductor element increases with time, and is represented by the following expression (7) where Vi is an input voltage, L is an inductance of the inductor element, and T1 is a period in which the second terminal is connected to the first terminal by the switch circuit.
IL=Vi/L×T1 (7)

On the other hand, while the switch circuit is connecting the second terminal to the third terminal, the current IL flowing through the inductor element decreases with time, and is represented by the following expression (8) where Vo is a voltage of the third terminal, L is the inductance of the inductor element, and T2 is a period in which the second terminal is connected to the third terminal by the switch circuit.
IL=−Vo/L×T2 (8)

The currents IL flowing through the inductor element obtained by the expression (7) and the expression (8) are equal to each other, and thus the voltage Vo of the third terminal is represented by the following expression (9) which is transformed from the expressions (7), (8).
Vo=T1/T2×Vi (9)

Therefore, the third terminal can be set at a predetermined negative voltage by the control circuit controlling a ratio of the connection period of the second terminal to the first terminal by the switch circuit and the connection period of the second terminal to the third terminal by the switch circuit. Consequently, the internal circuit can constantly receive the predetermined negative voltage as the power supply voltage. As a result, the internal circuit can be designed, being free from any restriction by the input voltage from an external power supply circuit. Further, the switch circuit does not consume power by heat generation unlike a variable resistor element of a linear regulator. Therefore, it is not needed to consider heat generation of an internal power supply circuit for designing the internal circuit, and a heat release capability of a package does not give a limitation on a permissible amount of heat generated by the internal circuit. This can contribute to improvement in function and speed of the semiconductor device.

In a preferable example of the third aspect of the present invention, a first switch of the switch circuit connects the second terminal to the first terminal. A second switch of the switch circuit connects the second terminal to the third terminal. This can facilitate designing of the switch circuit.

According to a fourth aspect of the present invention, a semiconductor device is, for example, mounted on a printed-circuit board or mounted in an electronics device. A first terminal receives an input voltage. A second terminal is connected to one end of an inductor element. A third terminal is connected to the other end of the inductor element. A first switch circuit connects the second terminal to one of the first terminal and a ground line. A second switch circuit connects the third terminal to one of a fourth terminal and the ground line. In order to set the fourth terminal at a predetermined voltage, a control circuit selects one of the first and second switch circuits based on a magnitude relation between a voltage of the fourth terminal and the input voltage, and switches a connection destination of the selected switch circuit according to the voltage of the fourth terminal while fixing a connection destination of the unselected switch circuit to a side that is not a ground line side (the first terminal side or the fourth terminal side). An internal circuit receives the voltage of the fourth terminal as a power supply voltage.

The semiconductor device as structured above operates similarly to one of the semiconductor devices of the first and second aspects described above according to the magnitude relation between the voltage of the fourth terminal and the input voltage. Consequently, the fourth terminal can be set either at a predetermined voltage that is lower than the input voltage or at a predetermined voltage that is higher than the input voltage. Therefore, the internal circuit can constantly receive the predetermined voltage as the power supply voltage even when the input voltage varies from a higher side to a lower side than the predetermined voltage or even when the input voltage varies from a lower side to a higher side than the predetermined voltage. As a result, the internal circuit can be designed, being free from any restriction by the input voltage from an external power supply circuit. Further, since the switch circuit does not consume power by heat generation unlike a variable resistor element of a linear regulator, it is not necessary to consider heat generation of an internal power supply circuit in designing the internal circuit, and a heat release capability of a package does not restrict a permissible amount of heat generated by the internal circuit. This can contribute to improvement in function and speed of the semiconductor device.

In a preferable example of the fourth aspect of the present invention, a first switch of the first switch circuit connects the second terminal to the first terminal. A second switch of the first switch circuit connects the second terminal to the ground line. A third switch of the second switch circuit connects the third terminal to the fourth terminal. A fourth switch of the second switch circuit connects the third terminal to the ground line. This can facilitate designing of the first and second switch circuits.

According to a fifth aspect of the present invention, a semiconductor device is, for example, mounted on a printed-circuit board or mounted in an electronics device. A first terminal receives an input voltage. A second terminal is connected to one end of an inductor element. A third terminal is connected to the other end of the inductor element. A first switch circuit connects the second terminal to one of the first terminal and a ground line. A second switch circuit connects the third terminal to one of a fourth terminal and the ground line. A control circuit fixes a connection destination of one of the first and second switch circuits to the ground line side and fixes a connection destination of the other of the first and second switch circuits to a side that is not the ground line side (the first terminal side or the fourth terminal side), according to a voltage of the fourth terminal in order to set the fourth terminal at a predetermined voltage. An internal circuit receives the voltage of the fourth terminal as a power supply voltage.

In the semiconductor device as structured above, while the first switch circuit is connecting the second terminal to the first terminal and the second switch circuit is connecting the third terminal to the ground line, a current IL flowing through the inductor element increases with time, and is represented by the following expression (10) where Vi is an input voltage, L is an inductance of the inductor element, and T1 is a period for connecting the second terminal to the first terminal by the switch circuit (a period during which the second switch circuit connects the third terminal to the ground line).
IL=Vi/L×T1 (10)

On the other hand, while the first switch circuit is connecting the second terminal to the ground line and the second switch circuit is connecting the third terminal to the fourth terminal, the current IL flowing through the inductor element decreases with time, and is represented by the following expression (11) where Vo is a voltage of the fourth terminal, L is the inductance of the inductor element, and T2 is a period for connection of the second terminal to the ground line by the first switch circuit (a period during which the second switch circuit connect the third terminal to the fourth terminal).
IL=Vo/L×T2 (11)

The currents IL flowing through the inductor element obtained by the expression (10) and the expression (11) are equal to each other, and thus the voltage Vo of the fourth terminal is represented by the following expression (12) which is transformed from the expressions (10), (11).
Vo=T1/T2×Vi (12)

Therefore, the fourth terminal can be set either at a predetermined voltage that is lower than the input voltage or at a predetermined voltage that is higher than the input voltage by the control circuit controlling a ratio of the connection period of the second terminal to the first terminal by the first switch circuit and the connection period of the second terminal to the ground line by the first switch circuit. Consequently, the internal circuit can constantly receive the predetermined voltage as the power supply voltage even when the input voltage varies from a higher side to a lower side than the predetermined voltage or even when the input voltage varies from a lower side to a higher side than the predetermined voltage. As a result, the internal circuit can be designed, being free from any restriction by the input voltage from an external power supply circuit. Further, since the switch circuits do not consume power by heat generation unlike a variable resistor element of a linear regulator, it is not necessary to consider heat generation of an internal power supply circuit in designing the internal circuit, and a heat release capability of a package does not restrict a permissible amount of heat generated by the internal circuit. This can contribute to improvement in function and speed of the semiconductor device.

In a preferable example of the fifth aspect of the present invention, a first switch of the first switch circuit connects the second terminal to the first terminal. A second switch of the first switch circuit connects the second terminal to the ground line. A third switch of the second switch circuit connects the third terminal to the fourth terminal. A fourth switch of the second switch circuit connects the third terminal to the ground line. This can facilitate designing of the first and second switch circuits.

According to a sixth aspect of the present invention, a semiconductor device is, for example, mounted on a printed-circuit board or mounted in an electronics device. A first terminal receives an input voltage. A second terminal is connected to one end of an inductor element. A third terminal is connected to the other end of the inductor element. A first switch circuit connects the second terminal to one of the first terminal and a fifth terminal. A second switch circuit connects the third terminal to one of a fourth terminal and a ground line. A control circuit alternately performs an operation of switching a connection destination of the second switch circuit according to a voltage of the fourth terminal in order to set the fourth terminal at a first predetermined voltage and an operation of switching a connection destination of the first switch circuit according to a voltage of the fifth terminal in order to set the fifth terminal at a second predetermined voltage. An internal circuit receives at least one of the voltage of the fourth terminal and the voltage of the fifth terminal as a power supply voltage.

The semiconductor device as structured above operates similarly to the semiconductor device according to the second aspect described above when the control circuit performs the operation of switching the connection destination of the second switch circuit, and operates similarly to the semiconductor device according to the third aspect described above while the control circuit performs the operation of switching the connection destination of the first switch circuit. Therefore, the fourth terminal can be set at the first predetermined voltage that is higher than the input voltage and the fifth terminal can be set at the negative second predetermined voltage. Consequently, the internal circuit can constantly receive the first predetermined voltage that is higher than the input voltage or the negative second predetermined voltage as the power supply voltage. As a result, the internal circuit can be designed, being free from any restriction by the input voltage from an external power supply circuit. Further, since the switch circuits do not consume power by heat generation unlike a variable resistor element of a linear regulator, it is not necessary to consider heat generation of an internal power supply circuit in designing the internal circuit, and a heat release capability of a package does not restrict a permissible amount of heat generated by the internal circuit. This can contribute to improvement in function and speed of the semiconductor device.

In a preferable example of the sixth aspect of the present invention, a first switch of the first switch circuit connects the second terminal to the first terminal. A second switch of the first switch circuit connects the second terminal to the fifth terminal. A third switch of the second switch circuit connects the third terminal to the fourth terminal. A fourth switch of the second switch circuit connects the third terminal to the ground line. This can facilitate designing of the first and second switch circuits.

### BRIEF DESCRIPTION OF THE DRAWINGS

The nature, principle, and utility of the invention will become more apparent from the following detailed description when read in conjunction with the accompanying drawings in which like parts are designated by identical reference numbers, in which:

FIG. 1 is a block diagram of a first principle of a semiconductor device of the present invention;

FIG. 2 is a block diagram of a second principle of the semiconductor device of the present invention;

FIG. 3 is a block diagram of a third principle of the semiconductor device of the present invention;

FIG. 4 is a block diagram of a fourth principle of the semiconductor device of the present invention;

FIG. 5 is a block diagram of a fifth principle of the semiconductor device of the present invention;

FIG. 6 is a block diagram of a sixth principle of the semiconductor device of the present invention;

FIG. 7 is a block diagram showing a first embodiment of the present invention;

FIG. 8 is an explanatory view showing the first embodiment of the present invention;

FIG. 9 is a timing chart showing an operation of a PWM comparator in FIG. 7;

FIG. 10 is a block diagram showing a second embodiment of the present invention;

FIG. 11 is a block diagram showing a third embodiment of the present invention;

FIG. 12 is a block diagram showing a fourth embodiment of the present invention;

FIG. 13 is a timing chart showing an operation of a PWM comparator in FIG. 12;

FIG. 14 is a timing chart showing an operation of the PWM comparator in FIG. 12;

FIG. 15 is a block diagram showing a fifth embodiment of the present invention;

FIG. 16 is a timing chart showing an operation of a PWM comparator in FIG. 15;

FIG. 17 is a block diagram showing a sixth embodiment of the present invention;

FIG. 18 is a timing chart showing an operation of a PWM comparator in FIG. 17;

FIG. 19 is a timing chart showing an operation of the PWM comparator in FIG. 17;

FIG. 20 is a block diagram showing a modification example of a control circuit in FIG. 7; and

FIG. 21 is a block diagram showing another modification example of the control circuit in FIG. 7.

### DESCRIPTION OF THE PREFERRED EMBODIMENTS

The present invention has been made in view of solving the following problems.

A linear regulator is advantageous in that it can be structured easily, but since it produces a difference between an input voltage and an output voltage by power consumption due to heat generation of a variable resistor element, it has a drawback of very poor efficiency to inhibit reduction in power consumption of semiconductor devices. Further, since a linear regulator is a heat generating source, for designing circuits around the linear regulator, how the heat generation therefrom affects its neighboring circuits has to be taken into consideration. Moreover, the heat generation of the linear regulator limits a permissible amount of heat generated by an internal circuit depending on a heat release capability of a package. This will obstruct higher function and a higher speed of a semiconductor device.

Further, since a linear regulator is capable of generating only an output voltage that is lower than an input voltage, the input voltage to be supplied has to be determined based on the highest power supply voltage if an internal power supply circuit constituted of a plurality of linear regulators generates a plurality of power supply voltages. This results in very poor generation efficiency of the output voltage of a linear regulator generating a lower-side power supply voltage out of the plural power supply voltages.

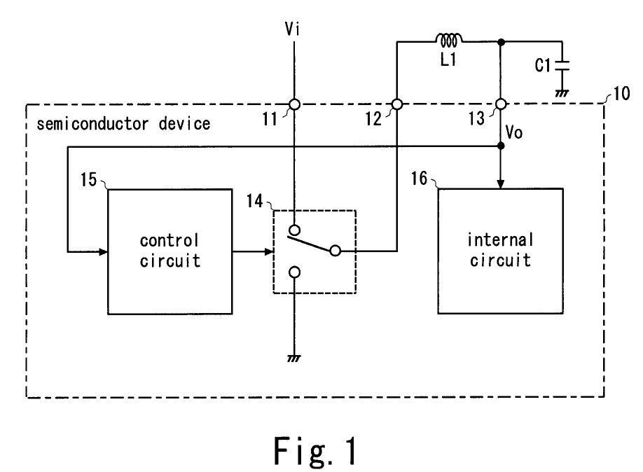

In the following the embodiments of the invention will be described in detail with reference to the accompanying drawings. FIG. 1 shows the first principle of the semiconductor device of the invention. A semiconductor device 10 includes a first terminal 11, a second terminal 12, a third terminal 13, a switch circuit 14, a control circuit 15, and an internal circuit 16. The first terminal 11 receives an input voltage Vi. The second terminal 12 is connected to one end of an inductor element L1. The third terminal 13 is connected to the other end of the inductor element L1. The third terminal 13 (the other end of the inductor element L1) is, for example, connected to a ground line via a capacitor element C1. The switch circuit 14 connects the second terminal 12 to one of the first terminal 11 and a ground line. The control circuit 15 switches a connection destination of the switch circuit 14 according to a voltage Vo of the third terminal 13 in order to set the third terminal 13 at a predetermined voltage. The internal circuit 16 receives the voltage Vo of the third terminal 13 as a power supply voltage.

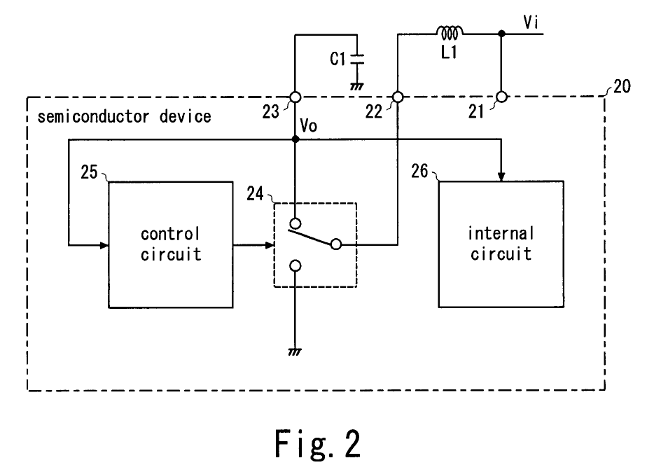

FIG. 2 shows the second basic principle of the semiconductor device of the invention. A semiconductor device 20 includes a first terminal 21, a second terminal 22, a third terminal 23, a switch circuit 24, a control circuit 25, and an internal circuit 26. The first terminal 21 receives an input voltage Vi. The second terminal 22 is connected to one end of an inductor element L1 receiving the input voltage Vi at the other end. The third terminal 23 is, for example, connected to a ground line via a capacitor element C1. The switch circuit 24 connects the second terminal 22 to one of the third terminal 23 and a ground line. The control circuit 25 switches a connection destination of the switch circuit 24 according to a voltage Vo of the third terminal 23 in order to set the third terminal 23 at a predetermined voltage. The internal circuit 26 receives the voltage Vo of the third terminal 23 as a power supply voltage.

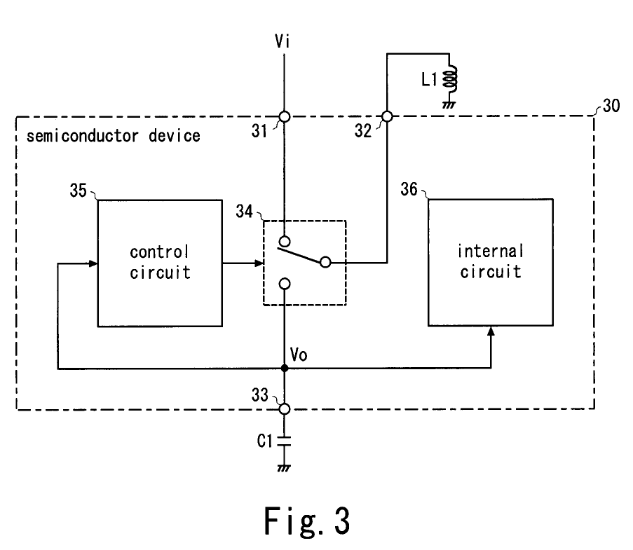

FIG. 3 shows the third basic principle of the semiconductor device of the invention. A semiconductor device 30 includes a first terminal 31, a second terminal 32, a third terminal 33, a switch circuit 34, a control circuit 35, and an internal circuit 36. The first terminal 31 receives an input voltage Vi. The second terminal 32 is connected to a ground line via an inductor element L1. The third terminal 33 is, for example, connected to a ground line via a capacitor element C1. The switch circuit 34 connects the second terminal 32 to one of the first terminal 31 and the third terminal 33. The control circuit 35 switches a connection destination of the switch circuit 34 according to a voltage Vo of the third terminal 33 in order to set the third terminal 33 at a predetermined voltage. The internal circuit 36 receives the voltage Vo of the third terminal 33 as a power supply voltage.

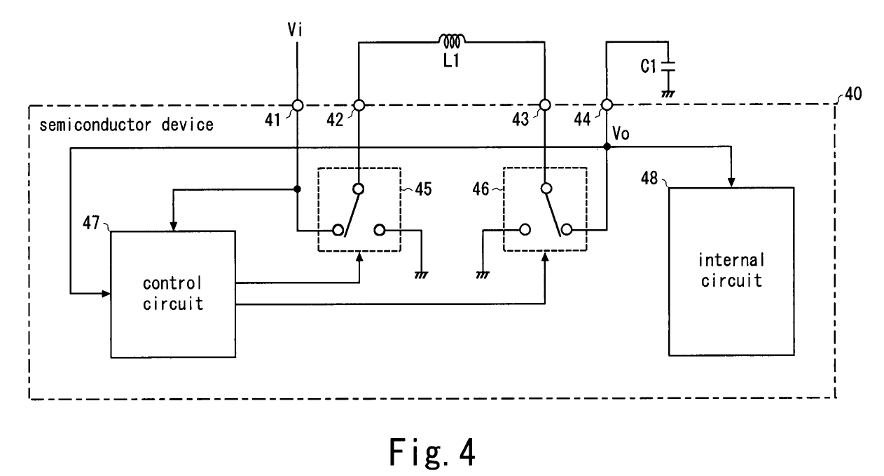

FIG. 4 shows the fourth basic principle of the semiconductor device of the invention. A semiconductor device 40 includes a first terminal 41, a second terminal 42, a third terminal 43, a fourth terminal 44, a fist switch circuit 45, a second switch circuit 46, a control circuit 47, and an internal circuit 48. The first terminal 41 receives an input voltage Vi. The second terminal 42 is connected to one end of an inductor element L1. The third terminal 43 is connected to the other end of the inductor element L1. The fourth terminal 44 is, for example, connected to a ground line via a capacitor element C1. The first switch circuit 45 connects the second terminal 42 to one of the first terminal 41 and a ground line. The second switch circuit 46 connects the third terminal 43 to one of the fourth terminal 44 and the ground line. In order to set the fourth terminal 44 at a predetermined voltage, the control circuit 47 selects one of the first and second switch circuits based on a magnitude relation between a voltage Vo of the fourth terminal 44 and the input voltage Vi, and switches a connection destination of the selected switch circuit according to the voltage Vo of the fourth terminal 44 while fixing a connection destination of the unselected switch circuit to a side that is not a ground line side (the first terminal 41 side or the fourth terminal 44 side). The internal circuit 48 receives the voltage Vo of the fourth terminal 44 as a power supply voltage.

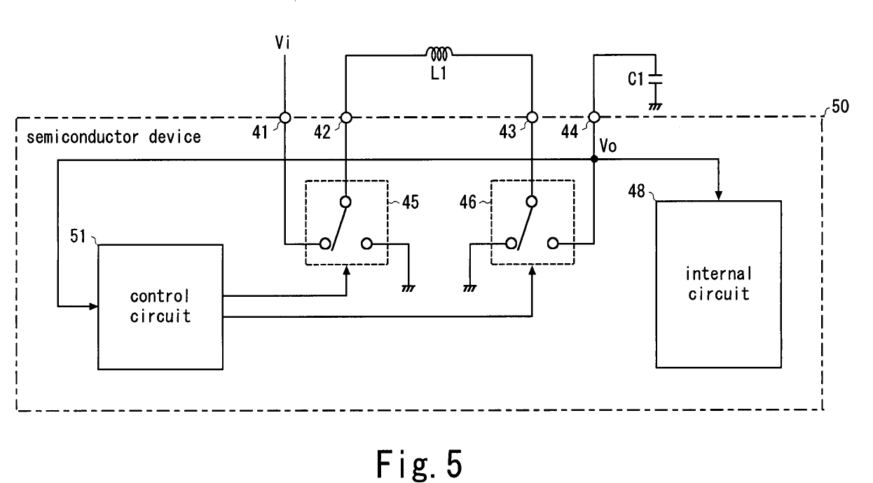

FIG. 5 shows the fifth basic principle of the semiconductor device of the invention. The same elements as in the FIG. 4 will be given the same numerals and symbols as those therein and their description will be omitted herein. A semiconductor device 50 is identical to the semiconductor device 40 of FIG. 4 except that it includes a control circuit 51 instead of the control circuit 46 of FIG. 4. The control circuit 51 fixes a connection destination of one of the first and second switch circuits 45, 46 to the ground line side and fixes a connection destination of the other of the first and second switch circuits 45, 46 to a side that is not the ground line side (the first terminal 41 side or the fourth terminal 44 side), according to a voltage Vo of the fourth terminal 44 in order to set the fourth terminal 44 at a predetermined voltage.

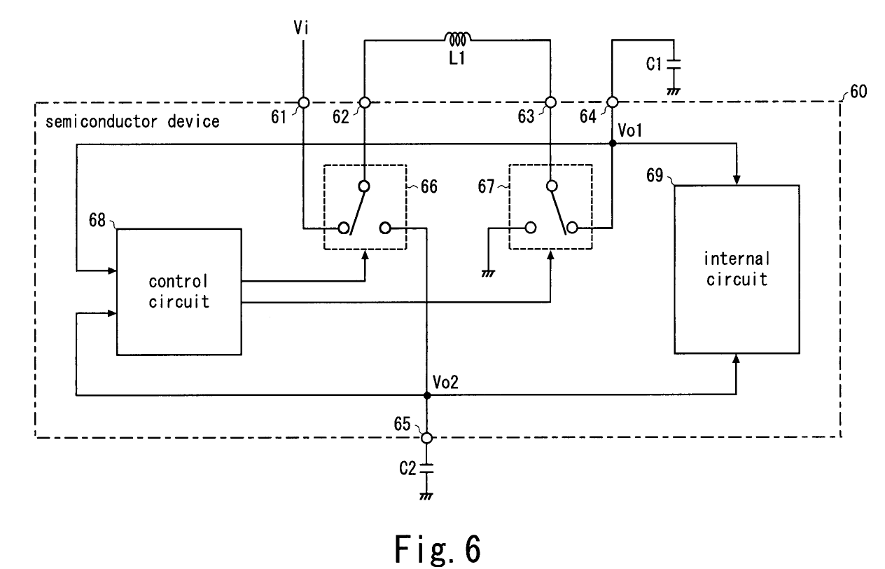

FIG. 6 shows the sixth basic principle of the semiconductor device of the invention. A semiconductor device 60 includes a first terminal 61, a second terminal 62, a third terminal 63, a fourth terminal 64, a fifth terminal 65, fist switch circuit 66, a second switch circuit 67, a control circuit 68, and an internal circuit 69. The first terminal 61 receives an input voltage Vi. The second terminal 62 is connected to one end of an inductor element L1. The third terminal 63 is connected to the other end of the inductor element L1. The fourth terminal 64 is, for example, connected to a ground line via a capacitor element C1. The fifth terminal 65 is, for example, connected to a ground line via a capacitor element C2. The first switch circuit 66 connects the second terminal 62 to one of the first terminal 61 and the fifth terminal 65. The second switch circuit 67 connects the third terminal 63 to one of the fourth terminal 64 and a ground line. The control circuit 68 alternately performs an operation of switching a connection destination of the second switch circuit 67 according to a voltage Vo1 of the fourth terminal 64 in order to set the fourth terminal 64 at a first predetermined voltage and an operation of switching a connection destination of the first switch circuit 66 according to a voltage Vo2 of the fifth terminal 65 in order to set the fifth terminal 65 at a second predetermined voltage. The internal circuit 69 receives at least one of the voltage Vo1 of the fourth terminal 64 and the voltage Vo2 of the fifth terminal 65 as a power supply voltage.

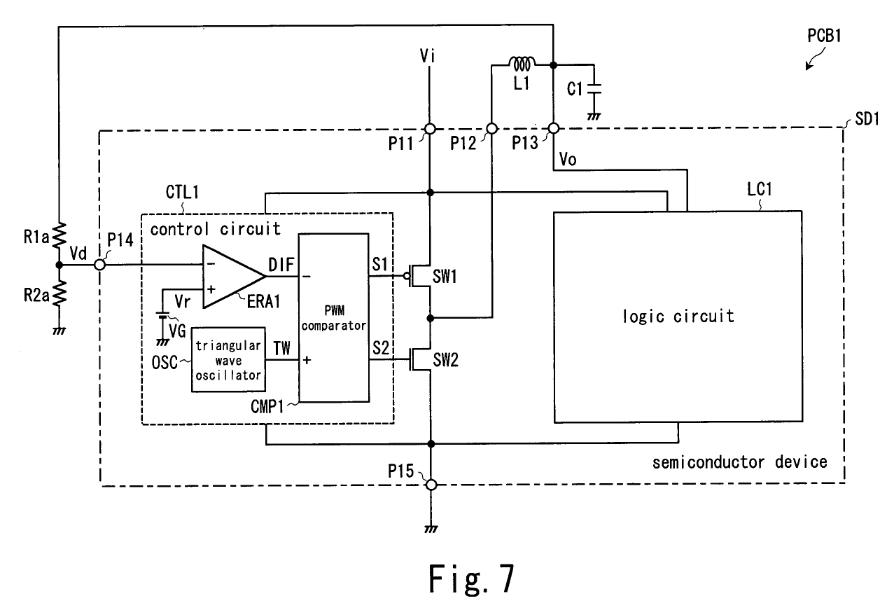

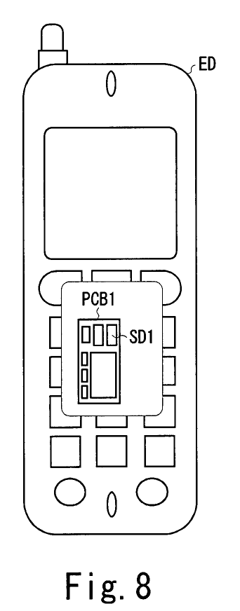

FIG. 7 and FIG. 8 show a first embodiment of the semiconductor device of the present invention. A semiconductor device SD1 has a first and a second switch SW1, SW2 (switch circuit), a control circuit CTL1, a logic circuit LC1 (internal circuit), and external terminals P11 to P15. The switches SW1, SW2, the control circuit CTL1 and the logic circuit LC1 are formed on, for example, a same semiconductor chip. Further, the semiconductor device SD1 is mounted on, for example, a printed-circuit board PCB1 mounted in an electronics device ED such as a cellular phone as shown in FIG. 8.

The external terminal P11 (first terminal) is connected to an external power supply circuit (not shown) on the printed-circuit board PCB1 to receive an input voltage Vi. The external terminal P12 (second terminal) and the external terminal P13 (third terminal) are connected to each other via a coil L1 (inductor element) on the printed-circuit board PCB1. A connection node of the coil L1 and the external terminal P13 is connected to a ground line via a smoothing capacitor C1 on the printed-circuit board PCB1. The connection node of the coil L1 and the external terminal P13 is also connected to the ground line via resistors R1a, R2a on the printed-circuit board PCB1. The external terminal P14 is connected to a connection node of the resistor R1a and the resistor R1b on the printed-circuit board PCB1. That is, the external terminal P14 receives a divided voltage Vd resulting from voltage division of a voltage Vo of the external terminal P13. The external terminal P15 is connected to the ground line on the printed-circuit board PCB1.

The control circuit CTL1 has a reference voltage generator VG, an error amplifier ERA1, a triangular wave oscillator OSC, and a PWM comparator CMP1 (voltage pulse converter). The reference voltage generator VG generates a reference voltage Vr to output it to the error amplifier ERA1. The error amplifier ERA1 receives the reference voltage Vr at its noninverting input terminal (+terminal) and receives the divided voltage Vd at its inverting input terminal (−terminal). The error amplifier ERA1 amplifies a difference between the divided voltage Vd and the reference voltage Vr to output a resultant voltage as a voltage difference signal DIF to an inverting input terminal of the PWM comparator CMP1. A voltage value of the voltage difference signal DIF is higher as the difference between the divided voltage Vd and the reference voltage Vr is larger. The triangular wave oscillator OSC generates a triangular wave signal TW (oscillation signal) with a predetermined cycle T to output it to a noninverting input terminal of the PWM comparator CMP1.

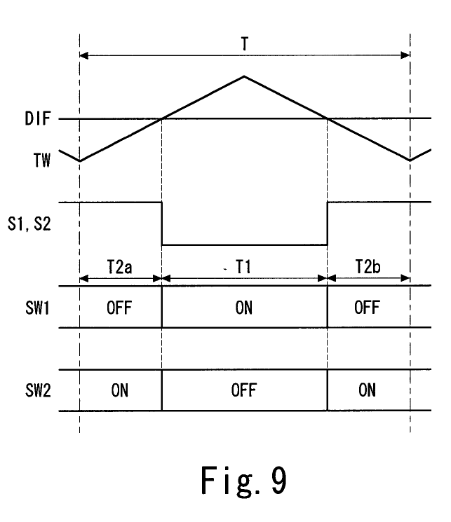

The PWM comparator CMP1, which is constituted of, for example, a voltage comparator, changes the levels of switch control signals S1, S2 to be outputted to the switches SW1, SW2 respectively, according to the magnitude relation between the voltage value of the voltage difference signal DIF and a voltage value of the triangular wave signal TW. The operation of the PWM comparator CMP1 will be detailed in FIG. 9. The switch SW1 is constituted of, for example, a pMOS transistor, and when the switch control signal S1 is at low level, the switch SW1 turns on to connect the external terminal P12 to the external terminal P11. The switch SW2 is constituted of, for example, a nMOS transistor, and when the switch control signal S2 is at high level, the switch SW2 turns on to connect the external terminal P12 to the external terminal P15 (i.e., a ground line). The logic circuit LC1 receives a voltage Vo of the external terminal P13 as a power supply voltage.

FIG. 9 shows an operation of the PWM comparator CMP1 in FIG. 7. The PWM comparator CMP1 fixes the switch control signals S1, S2 to high level when the voltage value of the voltage difference signal DIF is lower than the voltage value of the triangular wave signal TW. The PWM comparator CMP1 fixes the switch control signals S1, S2 to low level when the voltage value of the voltage difference signal DIF is higher than the voltage value of the triangular wave signal TW. This means that the switch control signals S1, S2 change in synchronization with inversion of the magnitude relation between the voltage value of the voltage difference signal DIF and the voltage value of the triangular wave signal TW. Since an increase ratio and a decrease ratio of the voltage value of the triangular wave signal TW are constant, it is possible to generate the switch control signals S1, S2 having a pulse width corresponding to the voltage value of the voltage difference signal DIF.

Therefore, the switch SW1 is off in a period T2 (T2a+T2b), of a period T of the triangular wave signal TW, during which the voltage value of the voltage difference signal DIF is lower than the voltage value of the triangular wave signal TW. The switch SW1 is on in a period T1, of the period T of the triangular wave signal TW, during which the voltage value of the voltage difference signal DIF is higher than the voltage value of the triangular wave signal TW. The switch SW2 is on in the period T2 (T2a+T2b), of the period T of the triangular wave signal TW, during which the voltage value of the voltage difference signal DIF is lower than the voltage value of the triangular wave signal TW. The switch SW2 is off in the period T1, of the period T of the triangular wave signal TW, during which the voltage value of the voltage difference signal DIF is higher than the voltage value of the triangular wave signal TW.

Since the voltage value of the voltage difference signal DIF is higher as the difference between the divided voltage Vd and the reference voltage Vr is larger, an occupying ratio of the ON period T1 of the switch SW1 to the period T is lower as the difference between the divided voltage Vd and the reference voltage Vr is larger. In other words, an occupying ratio of the OFF period T2 of the switch SW1 to the period T is higher as the difference between the divided voltage Vd and the reference voltage Vr is larger. The ON period T1 of the switch SW1 corresponds to a connection period of the external terminal P11 to the external terminal P12. The OFF period T2 of the switch SW1 corresponds to a connection period of the external terminal P12 to the external terminal P15 (ground line). Therefore, the voltage Vo of the external terminal P13 is represented by the aforesaid expression (3). The external terminal P13 can be set at a predetermined voltage that is lower than the input voltage Vi by the control circuit CTL1 controlling the ratios of the ON periods/OFF periods of the switches SW1, SW2.

In the first embodiment described above, the external terminal P13 can be set at the predetermined voltage that is lower than the input voltage Vi by the control circuit CTL1 controlling the ratios of the ON periods/OFF periods of the switches SW1, SW2. This allows the logic circuit LC1 to constantly receive as the power supply voltage the predetermined voltage that is lower than the input voltage Vi. As a result, the logic circuit LC1 can be designed, free from any restriction by the input voltage Vi from the external power supply circuit. Further, since the switches SW1, SW2 do not consume power by heat generation, it is not necessary to consider heat generation of an internal power supply circuit in designing the logic circuit LC1, and a permissible amount of heat generated by the logic circuit LC1 is not limited depending on a heat release capability of a package. This can contribute to improvement in function and speed of the semiconductor device SD1.

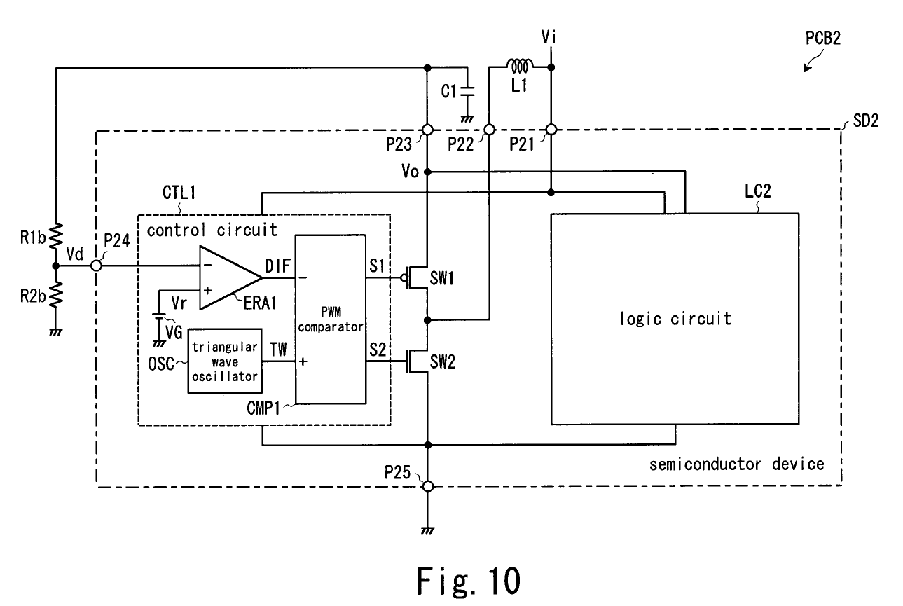

FIG. 10 shows a second embodiment of the semiconductor device of the present invention. The same reference numerals and symbols are used to designate the same elements as those described in the first embodiment, and detailed description thereof will not be given. A semiconductor device SD2 has a first and a second switch SW1, SW2 (switch circuit), a control circuit CTL1, a logic circuit LC2 (internal circuit), and external terminals P21 to P25. As in the first embodiment, the switches SW1, SW2, the control circuit CTL1, and the logic circuit LC2 are formed on, for example, a same semiconductor chip. The semiconductor device SD2 is mounted on, for example, a printed-circuit board PCB2 mounted in an electronics device such as a cellular phone.

The external terminal P21 (first terminal) is connected to an external power supply circuit (not shown) on the printed-circuit board PCB2 to receive an input voltage Vi. The external terminal P22 (second terminal) is connected to a connection node of the external power supply circuit and the external terminal P21 via a coil L1 (inductor element) on the printed-circuit board PCB2. The external terminal P23 (third terminal) is connected to a ground line via a smoothing capacitor C1 on the printed-circuit board PCB2. A connection node of the capacitor C1 and the external terminal P23 is connected to the ground line via resistors R1b, R2b on the printed-circuit board PCB2. The external terminal P24 is connected to a connection node of the resistor R1b and the resistor R2b on the printed-circuit board PCB2. That is, the external terminal P24 receives a divided voltage Vd resulting from voltage division of a voltage Vo of the external terminal P23. The external terminal P25 is connected to the ground line on the printed-circuit board PCB2. When a switch control signal S1 is at low level, the switch SW1 turns on to connect the external terminal P22 to the external terminal P23. When a switch control signal S2 is at high level, the switch SW2 turns on to connect the external terminal P22 to the external terminal P25 (i.e., the ground line). The logic circuit LC1 receives a voltage Vo of the external terminal P23 as a power supply voltage.

In the semiconductor device SD2 as structured above, an ON period T1 of the switch SW2 corresponds to a connection period of the external terminal P22 to the external terminal P25 (ground line). An OFF period T2 of the switch SW2 corresponds to a connection period of the external terminal P22 to the external terminal P23. Therefore, the voltage Vo of the external terminal P23 is represented by the aforesaid expression (6). The external terminal P23 can be set at a predetermined voltage that is higher than the input voltage Vi by the control circuit CTL1 controlling the ratios of the ON periods/OFF periods of the switches SW1, SW2.

In the second embodiment described above, the external terminal P23 can be set at the predetermined voltage that is higher than the input voltage Vi by the control circuit CTL1 controlling the ratios of the ON periods/OFF periods of the switches SW1, SW2. This allows the logic circuit LC2 to constantly receive as the power supply voltage the predetermined voltage that is higher than the input voltage Vi. As a result, as in the first embodiment, the logic circuit LC2 can be designed, free from any restriction by the input voltage Vi from the external power supply circuit. Further, since the switches SW1, SW2 do not consume power by heat generation, it is not necessary to consider heat generation of an internal power supply circuit in designing the logic circuit LC2, and a permissible amount of heat generated by the logic circuit LC2 is not limited depending on a heat release capability of a package. This can contribute to improvement in function and speed of the semiconductor device SD2.

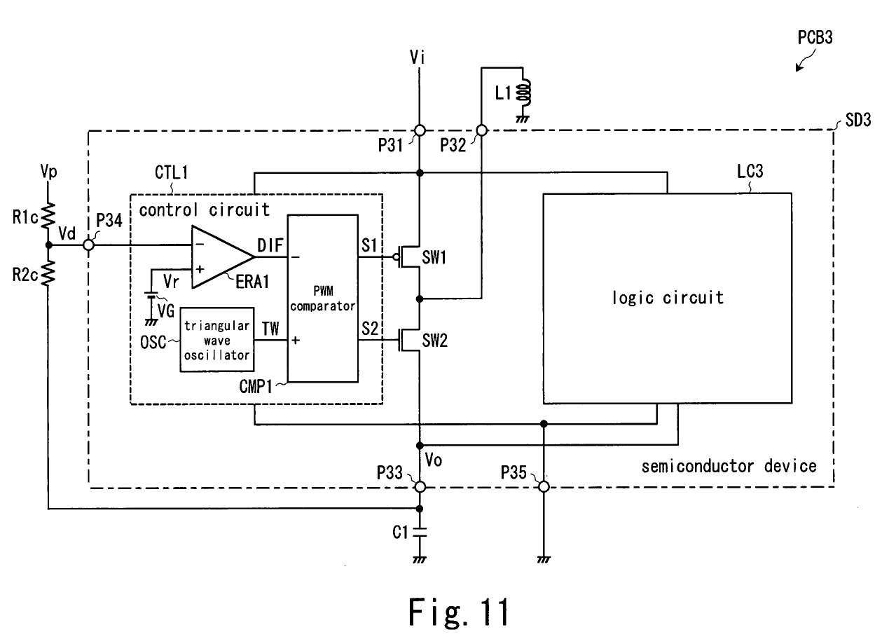

FIG. 11 shows a third embodiment of the semiconductor device of the present invention. The same reference numerals and symbols are used to designate the same elements as those described in the first embodiment, and detailed description thereof will not be given. A semiconductor device SD3 has a first and a second switch SW1, SW2 (switch circuit), a control circuit CTL1, a logic circuit LC3, and external terminals P31 to P35. As in the first embodiment, the switches SW1, SW2, the control circuit CTL1, and the logic circuit LC3 are formed on, for example, a same semiconductor chip. The semiconductor device SD3 is mounted on, for example, a printed-circuit board PCB3 mounted in an electronics device such a cellular phone.

The external terminal P31 (first terminal) is connected to an external power supply circuit (not shown) on the printed-circuit board PCB3 to receive an input voltage Vi. The external terminal P32 (second terminal) is connected to a ground line via a coil L1 (inductor element) on the printed-circuit board PCB3. The external terminal P33 (third terminal) is connected to the ground line via a smoothing capacitor C1 on the printed-circuit board PCB3. A connection node of the capacitor C1 and the external terminal P33 is connected to a supply line of a positive voltage Vp via resistors R1c, R2c on the printed-circuit board PCB3. The external terminal P34 is connected to a connection node of the resistor R1c and the resistor R2c on the printed-circuit board PCB3. That is, the external terminal P34 receives a divided voltage Vd resulting from voltage division of a voltage Vo of the external terminal P33. The external terminal P35 is connected to the ground line on the printed-circuit board PCB3. The switch SW1 turns on when a switch control signal S1 is at low level to connect the external terminal P32 to the external terminal P31. When a switch control signal S2 is at high level, the switch SW2 turns on to connect the external terminal P32 to the external terminal P33. The logic circuit LC3 receives the voltage Vo of the external terminal P33 as a power supply voltage.

In the semiconductor device SD3 as structured above, an ON period T1 of the switch SW1 corresponds to a connection period of the external terminal P32 to the external terminal P31. An OFF period T2 of the switch SW1 corresponds to a connection period of the external terminal P32 to the external terminal P33. Therefore, the voltage Vo of the external terminal P33 is represented by the aforesaid expression (9). The external terminal P33 can be set at a predetermined negative voltage by the control circuit CTL1 controlling the ratios of the ON periods/OFF periods of the switches SW1, SW2.

In the third embodiment described above, the external terminal P33 can be set at the predetermined negative voltage by the control circuit CTL1 controlling the ratios of the ON periods/OFF periods of the switches SW1, SW2. This allows the logic circuit LC3 to constantly receive the predetermined negative voltage as the power supply voltage. As a result, as in the first embodiment, the logic circuit LC3 can be designed, free from any restriction by the input voltage Vi from the external power supply circuit. Further, since the switches SW1, SW2 do not consume power by heat generation, it is not necessary to consider heat generation of an internal power supply circuit in designing the logic circuit LC3, and a permissible amount of heat generated by the logic circuit LC3 is not limited depending on a heat release capability of a package. This can contribute to improvement in function and speed of the semiconductor device SD3.

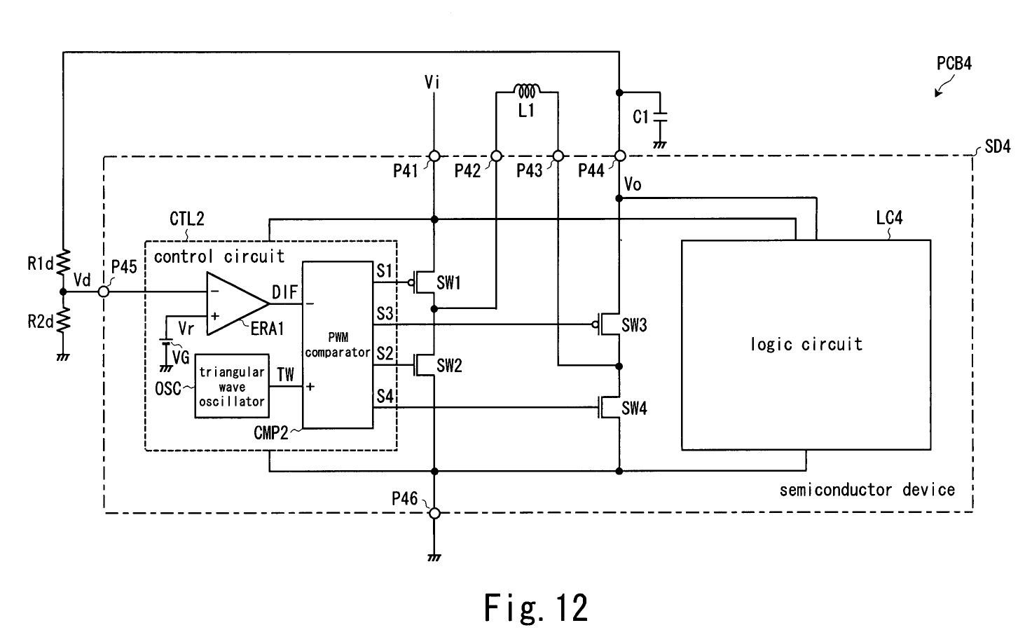

FIG. 12 shows a fourth embodiment of the semiconductor device of the present invention. The same reference numerals and symbols are used to designate the same elements as those described in the first embodiment, and detailed description thereof will not be given. A semiconductor device SD4 has a first and a second switch SW1, SW2 (first switch circuit), a third and a fourth switch SW3, SW4 (second switch circuit), a control circuit CTL2, a logic circuit LC4 (internal circuit), and external terminals P41 to P46. As in the first embodiment, the switches SW1 to SW4, the control circuit CTL2, and the logic circuit LC4 are formed on, for example, a same semiconductor chip. The semiconductor device SD4 is mounted on, for example, a printed-circuit board PCB4 mounted in an electronics device such as a cellular phone.

The external terminal P41 (first terminal) is connected to an external power supply circuit (not shown) on the printed-circuit board PCB4 to receive an input voltage Vi. The external terminal P42 (second terminal) and the external terminal P43 (third terminal) are connected to each other via a coil L1 (inductor element) on the printed-circuit board PCB4. The external terminal P44 (fourth terminal) is connected to a ground line via a smoothing capacitor C1 on the printed-circuit board PCB4. A connection node of the capacitor C1 and the external terminal P44 is connected to the ground line via resistors R1d, R2d on the printed-circuit board PCB4. The external terminal P45 is connected to a connection node of the resistor R1d and the resistor R2d on the printed-circuit board PCB4. That is, the external terminal P45 receives a divided voltage Vd resulting from voltage division of a voltage Vo of the external terminal P44. The external terminal P46 is connected to the ground line on the printed-circuit board PCB4.

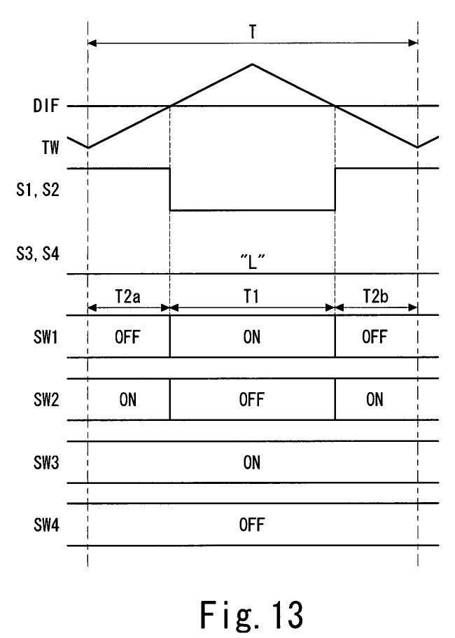

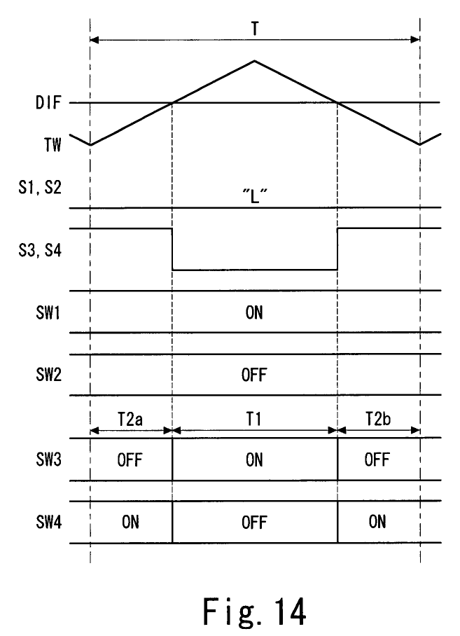

The control circuit CTL2 is the same as the control circuit CTL1 of the first embodiment except that it has a PWM comparator CMP2 (voltage pulse converter) in place of the PWM comparator CMP1. The PWM comparator CMP2, which is constituted of, for example, a voltage comparator, changes the levels of first switch control signals S1, S2 and second control signals S3, S4 to be outputted to the respective switches SW1 to SW4, according to the magnitude relation between a voltage value of a voltage difference signal DIF and a voltage value of a triangular wave signal TW. Operations of the PWM comparator CMP2 will be detailed in FIG. 13 and FIG. 14. When the switch control signal S1 is at low level, the switch SW1 turns on to connect the external terminal P42 to the external terminal P41. When the switch control signal S2 is at high level, the switch SW2 turns on to connect the external terminal P42 to the external terminal P46 (i.e., the ground line). The switch SW3 is constituted of, for example, a PMOS transistor, and when the switch control signal S3 is at low level, the switch SW3 turns on to connect the external terminal P43 to the external terminal P44. The switch SW4 is constituted of, for example, a nMOS transistor, and when the switch control signal S4 is at high level, the switch SW4 turns on to connect the external terminal P43 to the external terminal P46 (i.e., the ground line). The logic circuit LC4 receives a voltage Vo of the external terminal P44 as a power supply voltage.

FIG. 13 shows an operation of the PWM comparator CMP2 when the voltage Vo of the external terminal P44 is lower than the input voltage Vi. When the voltage Vo of the external terminal P44 is lower than the input voltage Vi, the PWM comparator CMP2 changes the levels of the switch control signals S1, S2 according to the magnitude relation between the voltage value of the voltage difference signal DIF and the voltage value of the triangular wave signal TW, while fixing the switch control signals S3, S4 to low level in order to turn on the switch SW3. When the voltage Vo of the external terminal P44 is lower than the input voltage Vi, the switch SW3 turns on and the switch SW4 turns off, so that the semiconductor device SD4 operates in the same manner as the semiconductor device SD1 of the first embodiment (FIG. 7). Therefore, the external terminal P44 is set at a predetermined voltage that is lower than the input voltage Vi.

FIG. 14 shows an operation of the PWM comparator CMP2 when the voltage Vo of the external terminal P44 is higher than the input voltage Vi. When the voltage Vo of the external terminal P44 is higher than the input voltage Vi, the PWM comparator CMP2 fixes the switch control signals S1, S2 to low level in order to turn on the switch SW1 while controlling the switch control signals S3, S4 according to the magnitude relation between the voltage value of the voltage difference signal DIF and the voltage value of the triangular wave signal TW. When the voltage Vo of the external terminal P44 is higher than the input voltage Vi, the switch SW1 turns on and the switch SW2 turns off, so that the semiconductor device SD4 operates in the same manner as the semiconductor device SD2 of the second embodiment (FIG. 10). Therefore, the external terminal P44 is set at a predetermined voltage that is higher than the input voltage Vi.

In the fourth embodiment described above, the semiconductor device SD4 operates in the same manner as either the semiconductor device SD1 of the first embodiment or the semiconductor device SD2 of the second embodiment according to the magnitude relation between the voltage Vo of the external terminal P44 and the input voltage Vi. Therefore, the external terminal P44 can be set either at the predetermined voltage that is lower than the input voltage Vi or at the predetermined voltage that is higher than the input voltage Vi. Consequently, even when the input voltage Vi varies from a higher side to a lower side than the predetermined voltage, or even when the input voltage Vi varies from a lower side to a higher side than the predetermined voltage, the logic circuit LC4 can constantly receive the predetermined voltage as the power supply voltage. As a result, designing of the logic circuit LC4 can be free from any restriction by the input voltage Vi from the external power supply circuit as in the first embodiment. Further, since the switches SW1 to SW4 do not consume power by heat generation, it is not necessary to consider heat generation of an internal power supply circuit in designing the logic circuit LC4, and a permissible amount of heat generated by the logic circuit LC4 is not limited depending on a heat release capability of a package. This can contribute to improvement in function and speed of the semiconductor device SD4.

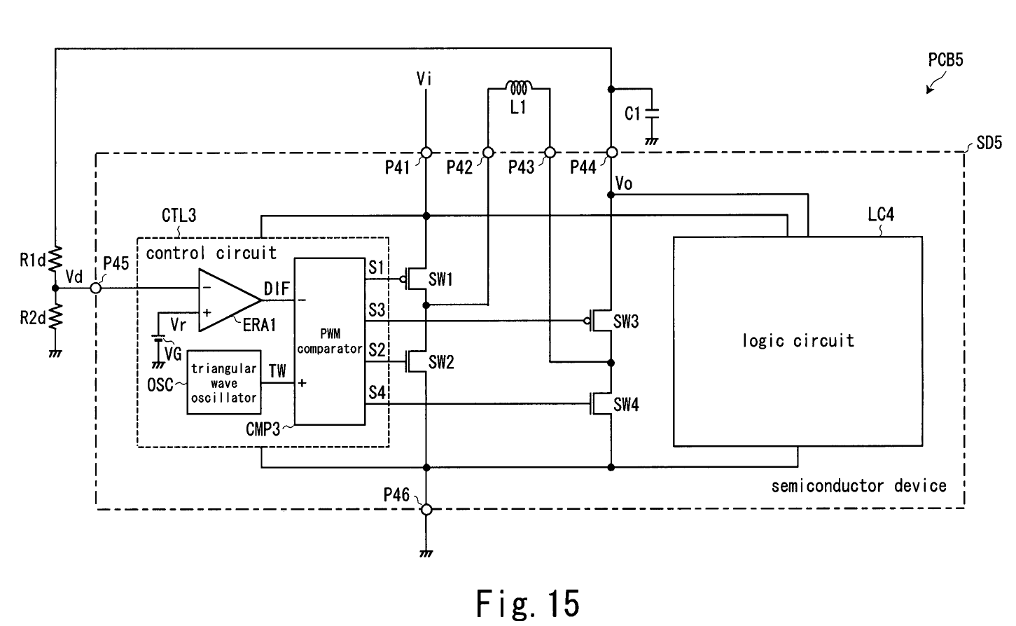

FIG. 15 shows a fifth embodiment of the semiconductor device of the present invention. The same reference numerals and symbols are used to designate the same elements as those described in the first and fourth embodiments, and detailed description thereof will not be given. A semiconductor device SD5 is the same as the semiconductor device SD4 of the fourth embodiment except that it has a control circuit CTL3 in place of the control circuit CTL2 of the fourth embodiment (FIG. 12). As in the first embodiment, switches SW1 to SW4, the control circuit CTL3, and a logic circuit LC4 are formed on, for example, a same semiconductor chip. The semiconductor device SD5 is mounted on, for example, a printed-circuit board PCB5 mounted in an electronics device such as a cellular phone.

The control circuit CTL3 is the same as the control circuit CTL1 of the first embodiment except that it has a PWM comparator CMP3 (voltage pulse converter) in place of the PWM comparator CMP1 of the first embodiment (FIG. 7). The PWM comparator CMP3, which is constituted of, for example, a voltage comparator, changes the levels of switch control signals S1 to S4 to be outputted to the respective switches SW1 to SW4, according to the magnitude relation between a voltage value of a voltage difference signal DIF and a voltage value of a triangular wave signal TW.

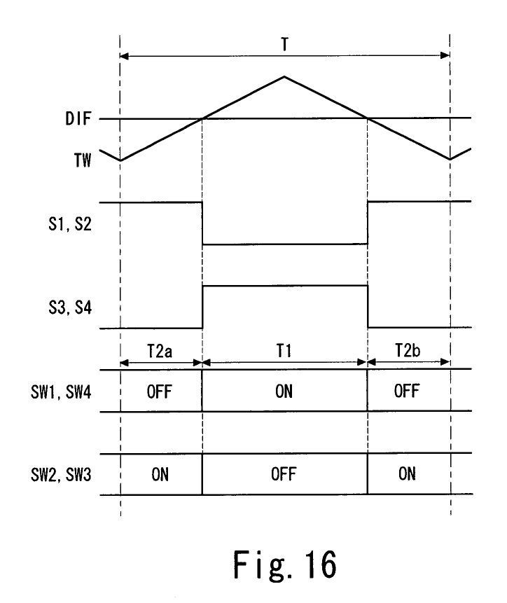

FIG. 16 shows an operation of the PWM comparator CMP3 in FIG. 15. When the voltage value of the voltage difference signal DIF is lower than the voltage value of the triangular wave signal TW, the PWM comparator CMP3 fixes the switch control signals S1, S2 to high level while fixing the switch control signals S3, S4 to low level. When the voltage value of the voltage difference signal DIF is higher than the voltage value of the triangular wave signal TW, the PWM comparator CMP3 fixes the switch control signals S1, S2 to low level while fixing the switch control signals S3, S4 to high level. That is, the switch control signals S1 to S4 change in synchronization with inversion of the magnitude relation between the voltage value of the voltage difference signal DIF and the voltage value of the triangular wave signal TW.

Therefore, the switches SW1, SW4 are off in a period T2 (T2a+T2b), of a period T of the triangular wave signal TW, during which the voltage value of the voltage difference signal DIF is lower than the voltage value of the triangular wave signal TW. The switches SW1, SW4 are on in a period T1, of the period T of the triangular wave signal TW, during which the voltage value of the voltage difference signal DIF is higher than the voltage value of the triangular wave signal TW. Meanwhile, the switches SW2, SW3 are on in the period T2 (T2a+T2b), of the period T of the triangular wave signal TW, during which the voltage value of the voltage difference signal DIF is lower than the voltage value of the triangular wave signal TW. The switches SW2, SW3 are off in the period T1, of the period T of the triangular wave signal TW, during which the voltage value of the voltage difference signal DIF is higher than the voltage value of the triangular wave signal TW.

Since the voltage value of the voltage difference signal DIF is higher as the difference between a divided voltage Vd and a reference voltage Vr is larger, an occupying ratio of the ON period T1 of the switches SW1, SW4 to the period T is lower as the difference between the divided voltage Vd and the reference voltage Vr is larger. In other words, an occupying ratio of the OFF period T2 of the switches SW1, SW4 to the period T is higher as the difference between the divided voltage Vd and the reference voltage Vr is larger. The ON period T1 of the switches SW1, SW4 corresponds to a connection period of the external terminal P42 to the external terminal P41 and a connection period of the external terminal P43 to the external terminal P46 (ground line). The OFF period T2 of the switches SW1, SW4 correspond to a connection period of the external terminal P42 to the external terminal P46 (ground line) and a connection period of the external terminal P43 to the external terminal P44. Therefore, a voltage Vo of the external terminal P44 is represented by the aforesaid expression (12). The external terminal P44 can be set at a predetermined voltage that is lower than an input voltage Vi or a predetermined voltage that is higher than the input voltage Vi by the control circuit CTL3 controlling the ratios of the ON periods/OFF periods of the switches SW1 to SW4. The fifth embodiment described above can also provide the same effects as those of the fourth embodiment.

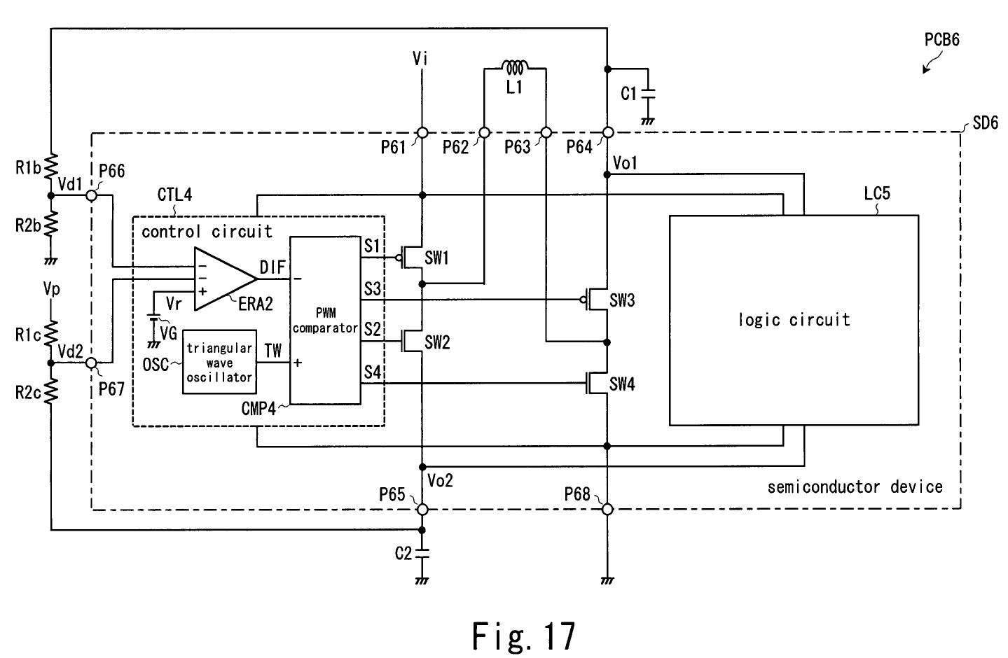

FIG. 17 shows a sixth embodiment of the semiconductor device of the present invention. The same reference numerals and symbols are used to designate the same elements as those described in the first to third embodiments, and detailed description thereof will not be given. A semiconductor device SD6 has a first and a second switch SW1, SW2 (first switch circuit), a third and a fourth switch SW3, SW4 (second switch circuit), a control circuit CTL4, a logic circuit LC5 (internal circuit), and external terminals P61 to P66. As in the first embodiment, the switches SW1 to SW4, the control circuit CTL4, and the logic circuit LC5 are formed on, for example, a same semiconductor chip. The semiconductor device SD6 is mounted on, for example, a printed-circuit board PCB6 mounted in an electronics device such as a cellular phone.

The external terminal P61 (first terminal) is connected to a power supply circuit (not shown) on the printed-circuit board PCB6 to receive an input voltage Vi. The external terminal P62 (second terminal) and the external terminal P63 (third terminal) are connected to each other via a coil L1 (inductor element) on the printed-circuit board PCB6. The external terminal P64 (fourth terminal) is connected to a ground line via a smoothing capacitor C1 on the printed-circuit board PCB6. A connection node of the capacitor C1 and the external terminal P64 is connected to the ground line via resistors R1b, R2b on the printed-circuit board PCB6. The external terminal P65 (fifth terminal) is connected to the ground line via a smoothing capacitor C2 on the printed-circuit board PCB6. A connection node of the capacitor C2 and the external terminal P65 is connected to a supply line of a positive voltage Vp via resistors R1c, R2c on the printed-circuit board PCB6. The external terminal P66 is connected to a connection node of the resistor R1b and the resistor R2b on the printed-circuit board PCB6. That is, the external terminal P66 receives a divided voltage Vd1 resulting from voltage division of a voltage Vo1 of the external terminal P64. The external terminal P67 is connected to a connection node of the resistor R1c and the resistor R2c on the printed-circuit board PCB6. That is, the external terminal P67 receives a divided voltage Vd2 resulting from voltage division of a voltage Vo2 of the external terminal P65. The external terminal P68 is connected to the ground line on the printed-circuit board PCB6.

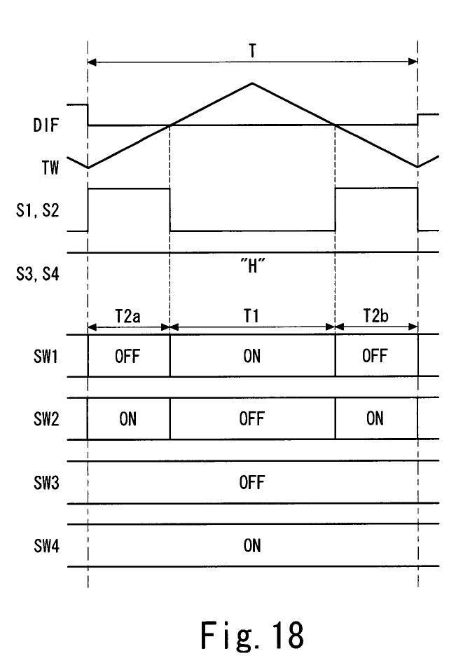

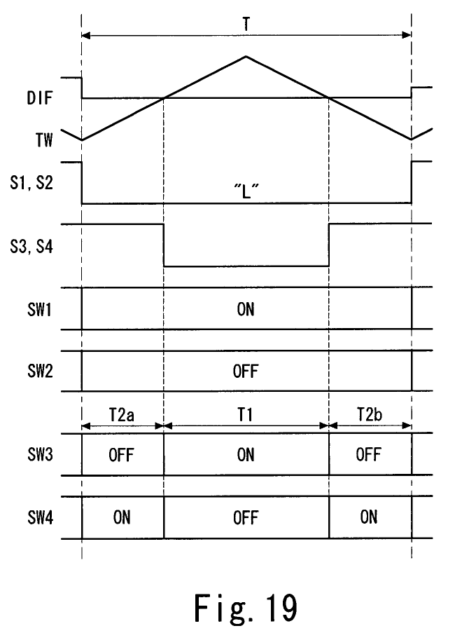

The control circuit CTL4 is the same as the control circuit CTL1 of the first embodiment except that it has an error amplifier ERA2 and a PWM comparator CMP4 (voltage pulse converter) in place of the error amplifier ERA1 and the PWM comparator CMP1 of the first embodiment (FIG. 7). The error amplifier ERA2 receives a reference voltage Vr at its noninverting input terminal (+terminal) and receives the divided voltages Vd1, Vd2 at its one inverting input terminal and other inverting input terminal (upper side and lower side in the drawing) respectively. The error amplifier ERA2 alternately selects the divided voltages Vd1, Vd2 at each cycle of the triangular wave signal TW and amplifies a difference between the selected divided voltage and the reference voltage Vr to output the resultant voltage as a voltage difference signal DIF to an inverting input terminal of the PWM comparator CMP4. The PWM comparator CMP4, which is constituted of, for example, a voltage comparator, changes the levels of first switch control signals S1, S2 and second switch control signals S3, S4 to be outputted to the respective switches SW1 to SW4, according to the magnitude relation between a voltage value of the voltage difference signal DIF and a voltage value of the triangular wave signal TW. Operations of the PWM comparator CMP4 will be detailed in FIG. 18 and FIG. 19.

When the switch control signal S1 is at low level, the switch SW1 turns on to connect the external terminal P62 to the external terminal P61. When the switch control signal S2 is at high level, the switch SW2 turns on to connect the external terminal P62 to the external terminal P65. When the switch control signal S3 is at low level, the switch SW3 turns on to connect the external terminal P63 to the external terminal P64. When the switch control signal S4 is at high level, the switch SW4 turns on to connect the external terminal P63 to the external terminal P68 (i.e., a ground line). The logic circuit LC5 receives the voltage Vo1 of the external terminal P64 and the voltage Vo2 of the external terminal P65 as a power supply voltage.

FIG. 18 shows an operation of the PWM comparator CMP4 when the error amplifier ERA2 selects the divided voltage Vd2. When the error amplifier ERA2 selects the divided voltage Vd2, the PWM comparator CMP4 changes the levels of the switch control signals S1, S2 according to the magnitude relation between a voltage value of the voltage difference signal DIF and a voltage value of the triangular signal TW while fixing the switch control signals S3, S4 to high level in order to turn on the switch SW4. The switch SW3 turns off and the switch SW4 turns on, so that the semiconductor device SD6 operates in the same manner as the semiconductor device SD3 of the third embodiment (FIG. 11). Therefore, the external terminal P65 is set at a predetermined negative voltage.

FIG. 19 shows an operation of the PWM comparator CMP4 when the error amplifier ERA2 selects the divided voltage Vd1. When the error amplifier ERA2 selects the divided voltage Vd1, the PWM comparator CMP4 fixes the switch control signals S1, S2 to low level in order to turn on the switch SW1 while changing the levels of the switch control signals S3, S4 according to the magnitude relation between the voltage value of the voltage difference signal DIF and the voltage value of the triangular signal TW. The switch SW1 turns on and the switch SW2 turns off, so that the semiconductor device SD6 operates in the same manner as the semiconductor device SD2 of the second embodiment (FIG. 10). Therefore, the external terminal P64 is set at a predetermined voltage that is higher than the input voltage Vi.

In the sixth embodiment described above, the semiconductor device SD6 operates in the same manner as the semiconductor device SD2 of the second embodiment when the control circuit CTL4 controls the switches SW3, SW4, and operates in the same manner as the semiconductor SD3 of the third embodiment when the control circuit CTL4 controls the SW1, SW2. Therefore, the external terminal P64 can be set at the predetermined voltage that is higher than the input voltage Vi and the external terminal P65 can be set at the negative predetermined voltage. This allows the logic circuit LC5 to constantly receive as the power supply voltage the predetermined voltage that is higher than the input voltage Vi or the predetermined negative voltage. As a result, designing of the logic circuit LC5 can be free from any restriction by the input voltage Vi from the external power supply circuit, as in the first embodiment. Further, since the switches SW1 to SW4 do not consume power by heat generation, it is not necessary to consider heat generation of an internal power supply circuit in designing the logic circuit LC5, and a permissible amount of heat generated by the logic circuit LC5 is not limited depending on a heat release capability of a package. This can contribute to improvement in function and speed of the semiconductor device SD6.

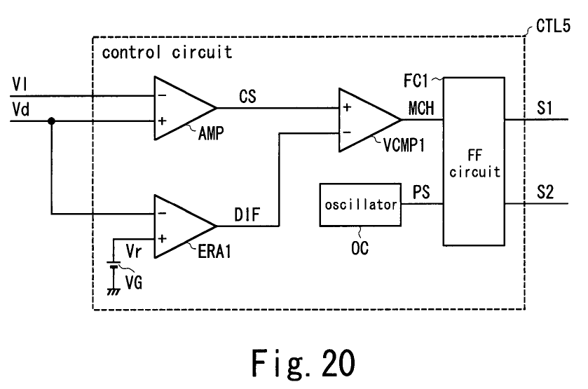

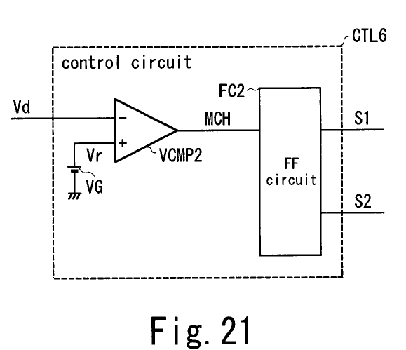

Incidentally, the first embodiment has described an example where the semiconductor SD1 (FIG. 7) has the control circuit CTL1 of a PWM control type. However, the present invention is not limited to such an embodiment. For example, the semiconductor device SD1 may have a control circuit CTL5 or CTL6 as shown in FIG. 20 and FIG. 21 respectively. FIG. 20 shows a modification example of the control circuit CTL1 in FIG. 7.

The same reference numerals and symbols are used to designate the same elements as those described in the first embodiment, and detailed description thereof will not be given. The control circuit CTL5 has a reference voltage generator VG, an error amplifier ERA1, an amplifier AMP (current monitoring circuit), a voltage comparator VCMP1, an oscillator OC, and a FF circuit FC1 (control signal generator). The amplifier AMP receives a divided voltage Vd at its noninverting input terminal and receives at its inverting input terminal a divided voltage V1 resulting from voltage division of a voltage of a connection node of switches S1, S2. The amplifier AMP amplifies a difference between the divided voltages Vd, V1 and outputs the resultant as a current signal CS to the voltage comparator VCMP1. Therefore, a voltage value of the current signal CS corresponds to a current flowing through a coil L1. The voltage comparator VCMP1 receives at its noninverting input terminal the current signal CS outputted from the amplifier AMP and receives at its inverting input terminal a voltage difference signal DIF outputted from the error amplifier ERA1. The voltage comparator VCMP1 activates a voltage match signal MCH to be outputted to the FF circuit FC1 when the voltage value of the current signal CS and the voltage value of the voltage difference signal DIF match each other. The oscillator OC outputs a pulse signal PS with a predetermined cycle. The FF circuit VC1, which is constituted by using, for example, an RS flipflop, changes switch control signals S1, S2 from high level to low level in response to the pulse signal PS, while changing the switch control signals S1, S2 from low level to high level in response to the activation of the voltage match signal MCH. When the control circuit CTL5 as structured above is applied to the semiconductor device SD1 of the first embodiment, the voltage Vo of the external terminal P13 can be also adjusted as in the first embodiment.

FIG. 21 shows another modification example of the control circuit CTL1 in FIG. 7. The same reference numerals and symbols are used to designate the same elements as those described in the first embodiment, and detailed description thereof will not be given. The control circuit CTL6 has a reference voltage generator VG, a voltage comparator VCMP2, and a FF circuit FC2 (pulse generator). The voltage comparator VCMP2 receives a divided voltage Vd at its inverting input terminal and receives a reference voltage Vr at its noninverting input terminal. The voltage comparator VCMP2 changes a voltage match signal MCH to be outputted to the FF circuit FC2 from low level to high level in response to matching of the divided voltage Vd and the reference voltage Vr. The FF circuit FC2 changes switch control signals S1, S2 from high level to low level in response to a rising edge of the voltage match signal MCH. When a predetermined period of time passes after changing the switch control signals S1, S2 from high level to low level, the FF circuit FC2 changes the switch control signals S1, S2 from low level to high level. Specifically, the FF circuit FC2 outputs one-shot pulse signals as the switch control signals S1, S2 in response to the rising edge of the voltage match signal MCH. When the control circuit CTL6 as structured above is applied to the semiconductor device SD1, the voltage Vo of the external terminal P13 can be also adjusted as in the first embodiment.

Further, the control circuits CTL5, CTL6 as structured above may be applied to each of the semiconductor devices SD2, SD3 of the second and third embodiments. Moreover, the control circuits CTL5, CTL6 may be structured such that a switch control signal to be controlled out of switch control signals S1 to S4 is switched as in the control circuits CTL2 to CTL4 of the fourth to sixth embodiments, and such control circuits CTL5, CTL6 may be applied to each of the semiconductor devices SD4 to SD6 of the fourth to sixth embodiments.

Incidentally, the first to sixth embodiments have described examples where the switches, the control circuit, and the logic circuit are formed on a same semiconductor chip. However, the present invention is not limited to such embodiments. For example, the switches, the control circuit, and the logic circuit may be formed on a plurality of semiconductor chips mounted in a same package.

The first to sixth embodiments have described examples where the coil L1 and the capacitors C1, C2 are connected to the semiconductor device on the printed-circuit board. However, the present invention is not limited to such embodiments. For example, the coil L1 and the capacitors C1, C2 may be mounted in a package of the semiconductor device.

The first to sixth embodiments have described examples where the voltage-dividing resistors R1a to R1d, R2a to R2d are connected to the semiconductor device on the printed-circuit board. However, the present invention is not limited to such embodiments. For example, the voltage-dividing resistors R1a to R1d, R2a to R2d may be formed in the semiconductor device.

The sixth embodiment has described an example where the selection period of the divided voltage Vd1 and the selection period of the divided voltage Vd2 by the error amplifier ERA2 correspond to the same period T of the triangular signal TW. However, the present invention is not limited to such an embodiment. For example, the selection period of the divided voltage Vd1 and the selection period of the divided voltage Vd2 by the error amplifier ERA2 may be made different in accordance with a ratio of a load of the voltage Vo1 of the external terminal 64 and a load of the voltage Vo2 of the external terminal 65. This enables efficient adjustment of the voltage Vo1 of the external terminal 64 and the voltage Vo2 of the external terminal 65.

The sixth embodiment has described an example where the logic circuit LC5 receives both the voltage Vo1 of the external terminal 64 and the voltage Vo2 of the external terminal 65 as the power supply voltage. However, the present invention is not limited to such an embodiment. For example, the logic circuit LC5 may receive as the power supply voltage only one of the voltage Vo1 of the external terminal 64 and the voltage Vo2 of the external terminal 65.

In the following the features of the present invention will be described.

(1) A semiconductor device according to the invention includes: a first terminal receiving an input voltage; a second terminal connected to one end of an inductor element; a third terminal connected to the other end of the inductor element; a switch circuit connecting the second terminal to one of the first terminal and a ground line; a control circuit switching a connection destination of the switch circuit according to a voltage of the third terminal in order to set the third terminal at a predetermined voltage; and an internal circuit receiving the voltage of the third terminal as a power supply voltage.

(2) In the semiconductor device according to item (1), the switch circuit includes a first switch connecting the second terminal to the first terminal, and a second switch connecting the second terminal to the ground line.

(3) In the semiconductor device according to item (2), the control circuit includes: an amplifier outputting a voltage difference signal according to a difference between a voltage following the voltage of the third terminal and a reference voltage; and a voltage pulse converter comparing voltage values of the voltage difference signal and of an oscillation signal with a predetermined cycle to find a magnitude relation therebetween, and outputting a pulse signal as a switch control signal to the first and second switches according to the magnitude relation.

(4) In the semiconductor device according to item (2), the control circuit includes: a current monitoring circuit outputting a current signal according to a current flowing through the inductor element; an amplifier outputting a voltage difference signal according to a difference between a voltage following the voltage of the third terminal and a reference voltage; and a control signal generator fixing a switch control signal to a first logic level in response to a pulse signal with a predetermined cycle, and fixing the switch control signal to a second logic level in response to a coincidence of voltage values of the current signal and of the voltage difference signal, the switch control signal being outputted to the first and second switches.

(5) In the semiconductor device according to item (2), the control circuit includes: a voltage comparator comparing a voltage following the voltage of the third terminal and a reference voltage, to output a voltage match signal when the two voltages coincide with each other; and a pulse generator outputting a pulse signal as a switch control signal to the first and second switches in response to the voltage match signal.

(6) In the semiconductor device according to item (2), the first and second switches are controlled such that when one turns on, the other turns off.

(7) In the semiconductor device according to item (1), the switch circuit, the control circuit, and the internal circuit are formed on a same semiconductor chip.

(8) The semiconductor device according to item (7) further includes at least one of the inductor element and a capacitor element which are mounted in a same package as the semiconductor chip. The capacitor element smoothes a voltage received by the internal circuit.

(9) In the semiconductor device according to item (1), the switch circuit, the control circuit, and the internal circuit are formed, respectively, on a plurality of semiconductor chips mounted in a same package.

(10) The semiconductor device according to item (9) further includes at least one of the inductor element and a capacitor element which are mounted in a same package as the semiconductor chips. The capacitor element smoothes a voltage received by the internal circuit.

(11) A semiconductor device according to the present invention includes: a first terminal receiving an input voltage; a second terminal connected to one end of an inductor element receiving the input voltage at the other end; a third terminal; a switch circuit connecting the second terminal to one of the third terminal and a ground line; a control circuit switching a connection destination of the switch circuit according to a voltage of the third terminal in order to set the third terminal at a predetermined voltage; and an internal circuit receiving the voltage of the third terminal as a power supply voltage.

(12) In the semiconductor device according to item (11), the switch circuit includes a first switch connecting the second terminal to the third terminal, and a second switch connecting the second terminal to the ground line.

(13) In the semiconductor device according to item (12), the control circuit includes: an amplifier outputting a voltage difference signal according to a difference between a voltage following the voltage of the third terminal and a reference voltage; and a voltage pulse converter comparing voltage values of the voltage difference signal and of an oscillation signal with a predetermined cycle to find a magnitude relation therebetween, and outputting a pulse signal as a switch control signal to the first and second switches according to the magnitude relation.

(14) In the semiconductor device according to item (12), the control circuit includes: a current monitoring circuit outputting a current signal according to a current flowing through the inductor element; an amplifier outputting a voltage difference signal according to a difference between a voltage following the voltage of the third terminal and a reference voltage; and a control signal generator fixing a switch control signal to a first logic level in response to a pulse signal with a predetermined cycle, and fixing the switch control signal to a second logic level in response to a coincidence of voltage values of the current signal and of the voltage difference signal, the switch control signal being outputted to the first and second switches.

(15) In the semiconductor device according to item (12), the control circuit includes: a voltage comparator comparing a voltage following the voltage of the third terminal and a reference voltage, to output a voltage match signal when the two voltages coincide with each other; and a pulse generator outputting a pulse signal as a switch control signal to the first and second switches in response to the voltage match signal.

(16) In the semiconductor device according to item (12), the first and second switches are controlled such that when one turns on, the other turns off.

(17) In the semiconductor device according to item (11), the switch circuit, the control circuit, and the internal circuit are formed on a same semiconductor chip.

(18) The semiconductor device according to item 17 further includes at least one of the inductor element and a capacitor element which are mounted in a same package as the semiconductor chip. The capacitor element smoothes a voltage received by the internal circuit.

(19) In the semiconductor device according to item (11), the switch circuit, the control circuit, and the internal circuit are formed, respectively, on a plurality of semiconductor chips mounted in a same package.

(20) The semiconductor device according to item (19) further includes at least one of the inductor element and a capacitor element which are mounted in a same package as the semiconductor chips. The capacitor element smoothes a voltage received by the internal circuit.

(21) A semiconductor device according to the present invention includes: a first terminal receiving an input voltage; a second terminal connected to a ground line via an inductor element; a third terminal; a switch circuit connecting the second terminal to one of the first terminal and the third terminal; a control circuit switching a connection destination of the switch circuit according to a voltage of the third terminal in order to set the third terminal at a predetermined voltage; and an internal circuit receiving the voltage of the third terminal as a power supply voltage.

(22) In the semiconductor device according to item (21), the switch circuit includes a first switch connecting the second terminal to the first terminal, and a second switch connecting the second terminal to the third terminal.

(23) In the semiconductor device according to item (22), the control circuit includes: an amplifier outputting a voltage difference signal according to a difference between a voltage following the voltage of the third terminal and a reference voltage; and a voltage pulse converter comparing voltage values of the voltage difference signal and of an oscillation signal with a predetermined cycle to find a magnitude relation therebetween, and outputting a pulse signal as a switch control signal to the first and second switches according to the magnitude relation.

(24) In the semiconductor device according to item (22), the control circuit includes: a current monitoring circuit outputting a current signal according to a current flowing through the inductor element; an amplifier outputting a voltage difference signal according to a difference between a voltage following the voltage of the third terminal and a reference voltage; and a control signal generator fixing a switch control signal to a first logic level in response to a pulse signal with a predetermined cycle, and fixing the switch control signal to a second logic level in response to a coincidence of voltage values of the current signal and of the voltage difference signal, the switch control signal being outputted to the first and second switches.

(25) In the semiconductor device according to item (22), the control circuit includes: a voltage comparator comparing a voltage following the voltage of the third terminal and a reference voltage, to output a voltage match signal when the two voltages coincide with each other; and a pulse generator outputting a pulse signal as a switch control signal to the first and second switches in response to the voltage match signal.

(26) In the semiconductor device according to item (22), the first and second switches are controlled such that when one turns on, the other turns off.

(27) In the semiconductor device according to item (21), the switch circuit, the control circuit, and the internal circuit are formed on a same semiconductor chip.

(28) The semiconductor device according to item (27) further includes at least one of the inductor element and a capacitor element which are mounted in a same package as the semiconductor chip. The capacitor element smoothes a voltage received by the internal circuit.

(29) In the semiconductor device according to item (21), the switch circuit, the control circuit, and the internal circuit are formed, respectively, on a plurality of semiconductor chips mounted in a same package.

(30) The semiconductor device according to item (29) further includes at least one of the inductor element and a capacitor element which are mounted in a same package as the semiconductor chips. The capacitor element smoothes a voltage received by the internal circuit.

(31) A semiconductor device according to the present invention includes: a first terminal receiving an input voltage; a second terminal connected to one end of an inductor element; a third terminal connected to the other end of the inductor element; a fourth terminal; a first switch circuit connecting the second terminal to one of the first terminal and a ground line; a second switch circuit connecting the third terminal to one of the fourth terminal and the ground line; a control circuit which, in order to set the fourth terminal at a predetermined voltage, selects one of the first and second switch circuits according to a magnitude relation between a voltage of the fourth terminal and the input voltage, and switches a connection destination of the selected switch circuit according to the voltage of the fourth terminal while fixing a connection destination of an unselected switch circuit to a side that is not a ground line side; and an internal circuit receiving the voltage of the fourth terminal as a power supply voltage.

(32) In the semiconductor device according to item (31), the first switch circuit includes a first switch connecting the second terminal to the first terminal, and a second switch connecting the second terminal to the ground line; and the second switch circuit includes a third switch connecting the third terminal to the fourth terminal, and a fourth switch connecting the third terminal to the ground line.

(33) In the semiconductor device according to item (32), the control circuit includes: an amplifier outputting a voltage difference signal according to a difference between a voltage following the voltage of the fourth terminal and a reference voltage; and a voltage pulse converter comparing voltage values of the voltage difference signal and of an oscillation signal with a predetermined cycle to find a magnitude relation therebetween, and according to the magnitude relation, outputting a pulse signal as a first switch control signal to the first and second switches when the voltage of the fourth terminal is lower than the input voltage and outputting the pulse signal as a second switch control signal to the third and fourth switches when the voltage of the fourth terminal is higher than the input voltage.

(34) In the semiconductor device according to item (33), the control circuit fixes a level of the second switch control signal in order to turn on the third switch when the voltage of the fourth terminal is lower than the input voltage, and fixes a level of the first switch control signal in order to turn on the first switch when the voltage of the fourth terminal is higher than the input voltage.

(35) In the semiconductor device according to item (32), the control circuit includes: a current monitoring circuit outputting a current signal according to a current flowing through the inductor element; an amplifier outputting a voltage difference signal according to a difference between a voltage following the voltage of the fourth terminal and a reference voltage; and a control signal generator which, when the voltage of the fourth terminal is lower than the input voltage, fixes a first switch control signal to be outputted to the first and second switches to a first logic level in response to a pulse signal with a predetermined cycle and which fixes the first switch control signal to a second logic level in response to a coincidence of voltage values of the current signal and of the voltage difference signal, and which, when the voltage of the fourth terminal is higher than the input voltage, fixes a second switch control signal to be outputted to the third and fourth switches to the first logic level in response to the pulse signal and fixes the second switch control signal to the second logic level in response to the coincidence of the voltage values of the current signal and of the voltage difference signal.

(36) In the semiconductor device according to item (35), the control circuit fixes a level of the second switch control signal in order to turn on the third switch when the voltage of the fourth terminal is lower than the input voltage, and fixes a level of the first switch control signal in order to turn on the first switch when the voltage of the fourth terminal is higher than the input voltage.

(37) In the semiconductor device according to item (32), the control circuit includes: a voltage comparator comparing a voltage following the voltage of the fourth terminal and a reference voltage, to output a voltage match signal indicating a coincidence of the two voltages; and a pulse generator which outputs a pulse signal as a first switch control signal to the first and second switches in response to the voltage match signal when the voltage of the fourth terminal is lower than the input voltage, and which outputs the pulse signal as a second control signal to the third to fourth switches in response to the voltage match signal when the voltage of the fourth terminal is higher than the input voltage.

(38) In the semiconductor device according to item (37), the control circuit fixes a level of the second switch control signal in order to turn on the third switch when the voltage of the fourth terminal is lower than the input voltage, and fixes a level of the first switch control signal in order to turn on the first switch when the voltage of the fourth terminal is higher than the input voltage.

(39) In the semiconductor device according to item (32), the first and second switches are controlled such that when one turns on, the other turns off; and the third and fourth switches are controlled such that when one turns on, the other turns off.

(40) In the semiconductor device according to item (31), the first and second switch circuits, the control circuit, and the internal circuit are formed on a same semiconductor chip.

(41) In the semiconductor device according to item (40) further includes at least one of the inductor element and a capacitor element which are mounted in a same package as the semiconductor chip. The capacitor element smoothes a voltage received by the internal circuit.

(42) In the semiconductor device according to item (31), the first and second switch circuits, the control circuit, and the internal circuit are formed, respectively, on a plurality of semiconductor chips mounted in a same package.

(43) In the semiconductor device according to item (42) further includes at least one of the inductor element and a capacitor element which are mounted in a same package as the semiconductor chips. The capacitor element smoothes a voltage received by the internal circuit.

(44) A semiconductor device according to the present invention includes: a first terminal receiving an input voltage; a second terminal connected to one end of an inductor element; a third terminal connected to the other end of the inductor element; a fourth terminal; a first switch circuit connecting the second terminal to one of the first terminal and a ground line; a second switch circuit connecting the third terminal to one of the fourth terminal and the ground line; a control circuit fixing a connection destination of one of the first and second switch circuits to the ground line and fixing a connection destination of the other of the first and second switch circuits to a side that is not a ground line side according to a voltage of the fourth terminal in order to set the fourth terminal at a predetermined voltage; and an internal circuit receiving the voltage of the fourth terminal as a power supply voltage.

(45) In the semiconductor device according to item (44), the first switch circuit includes a first switch connecting the second terminal to the first terminal, and a second switch connecting the second terminal to the ground line; and the second switch circuit includes a third switch connecting the third terminal to the fourth terminal, and a fourth switch connecting the third terminal to the ground line.

(46) In the semiconductor device according to item (45), the control circuit includes: an amplifier outputting a voltage difference signal according to a difference between a voltage following the voltage of the fourth terminal and a reference voltage; and a voltage pulse converter comparing voltage values of the voltage difference signal and of an oscillation signal with a predetermined cycle to find a magnitude relation therebetween, and outputting a pulse signal as a switch control signal to the first to fourth switches according to the magnitude relation.

(47) In the semiconductor device according to item (45), the control circuit includes: a current monitoring circuit outputting a current signal according to a current flowing through the inductor element; an amplifier outputting a voltage difference signal according to a difference between a voltage following the voltage of the fourth terminal and a reference voltage; and a control signal generator fixing a switch control signal to be outputted to the first to fourth switches to a first logic level in response to a pulse signal with a predetermined cycle and fixing the switch control signal to a second logic level in response to a coincidence of voltage values of the current signal and of the voltage difference signal.

(48) In the semiconductor device according to item (45), the control circuit includes: a voltage comparator comparing a voltage following the voltage of the fourth terminal and a reference voltage to output a voltage match signal indicating a coincidence of the two voltages; and a pulse generator outputting a pulse signal as a switch control signal to the first to forth switches in response to the voltage match signal.

(49) In the semiconductor device according to item (45), a pair of the first and fourth switches and a pair of the second and third switches are controlled such that when one pair turns on, the other pair turns off.

(50) In the semiconductor device according to item (44), the first and second switch circuits, the control circuit, and the internal circuit are formed on a same semiconductor chip.

(51) The semiconductor device according to item (50) further includes at least one of the inductor element and a capacitor element which are mounted in a same package as the semiconductor chip. The capacitor element smoothes a voltage received by the internal circuit.

(52) In the semiconductor device according to item (44), the first and second switch circuits, the control circuit, and the internal circuit are formed, respectively, on a plurality of semiconductor chips mounted in a same package.

(53) The semiconductor device according to item (52) further includes at least one of the inductor element and a capacitor element which are mounted in a same package as the semiconductor chips. The capacitor element smoothes a voltage received by the internal circuit.

(54) A semiconductor device according to the present invention includes: a first terminal receiving an input voltage; a second terminal connected to one end of an inductor element; a third terminal connected to the other end of the inductor element; a fourth terminal; a fifth terminal; a first switch circuit connecting the second terminal to one of the first and fifth terminals; a second switch circuit connecting the third terminal to one of the fourth terminal and a ground line; a control circuit alternately performing an operation of switching a connection destination of the second switch circuit according to a voltage of the fourth terminal in order to set the fourth terminal at a first predetermined voltage and an operation of switching a connection destination of the first switch circuit according to a voltage of the fifth terminal in order to set the fifth terminal at a second predetermined voltage; and an internal circuit receiving at least one of the voltages of the fourth terminal and of the fifth terminal as a power supply voltage.

(55) In the semiconductor device according to item (54), the first switch circuit includes a first switch connecting the second terminal to the first terminal, and a second switch connecting the second terminal to the fifth terminal; and the second switch circuit includes a third switch connecting the third terminal to the fourth terminal, and a fourth switch connecting the third terminal to the ground line.

(56) In the semiconductor device according to item (55), the control circuit includes: an amplifier alternately selecting a voltage following the voltage of the fourth terminal and a voltage following the voltage of the fifth terminal, to output a voltage difference signal according to a difference between the selected voltage and a reference voltage; and a voltage pulse converter comparing voltage values of the voltage difference signal and of an oscillation signal with a predetermined cycle to find a magnitude relation therebetween, and according to the magnitude relation, outputting a pulse signal as a first switch control signal to the first and second switches when the amplifier selects the voltage following the voltage of the fifth terminal and outputting the pulse signal as a second switch control signal to the third and fourth switches when the amplifier selects the voltage following the voltage of the fourth terminal.

(57) In the semiconductor device according to item (56), the control circuit fixes a level of the second switch control signal in order to turn on the fourth switch upon the selection of the voltage following the voltage of the fifth terminal, and fixes a level of the first switch control signal in order to turn on the first switch upon the selection of the voltage following the voltage of the fourth terminal.

(58) In the semiconductor device according to item (55), the control circuit includes: a current monitoring circuit outputting a current signal according to a current flowing through the inductor element; an amplifier alternately selecting a voltage following the voltage of the fourth terminal and a voltage following the voltage of the fifth terminal to output a voltage difference signal according to a difference between the selected voltage and a reference voltage; and a control signal generator which, when the amplifier selects the voltage following the voltage of the fifth terminal, fixes a first switch control signal to be outputted to the first and second switches to a first logic level in response to a pulse signal with a predetermined cycle and fixes the first switch control signal to a second logic level in response to a coincidence of voltage values of the current signal and of the voltage difference signal, and which, when the amplifier selects the voltage following the voltage of the fourth terminal, fixes a second switch control signal to be outputted to the third and fourth switches to the first logic level in response to the pulse signal and fixes the second switch control signal to the second logic level in response to the coincidence of the voltage values of the current signal and of the voltage difference signal.

(59) In the semiconductor device according to item (58), the control circuit fixes a level of the second switch control signal in order to turn on the fourth switch upon the selection of the voltage following the voltage of the fifth terminal, and fixes a level of the first switch control signal in order to turn on the first switch upon the selection of the voltage following the voltage of the fourth terminal.

(60) In the semiconductor device according to item (55), the control circuit includes: a voltage comparator alternately selecting a voltage following the voltage of the fourth terminal and a voltage following the voltage of the fifth terminal and comparing the selected voltage and a reference voltage to output a voltage match signal indicating a coincidence of the two voltages; and a pulse generator which, in response to the voltage match signal, outputs a pulse signal as a first switch control signal to the first second switches when the voltage comparator selects the voltage following the voltage of the fifth terminal, and outputs the pulse signal as a second switch control signal to the third and fourth switches when the voltage comparator selects the voltage following the voltage of the fourth terminal.

(61) In the semiconductor device according to item (60), the control circuit fixes a level of the second switch control signal in order to turn on the fourth switch upon the selection of the voltage following the voltage of the fifth terminal, and fixes a level of the first switch control signal in order to turn on the first switch upon the selection of the voltage following the voltage of the fourth terminal.

(62) In the semiconductor device according to item (55), the first and second switches are controlled such that when one turns on, the other turns off; and the third and fourth switches are controlled such that when one turns on, the other turns off.

(63) In the semiconductor device according to item (54), the first and second switch circuits, the control circuit, and the internal circuit are formed on a same semiconductor chip.

(64) The semiconductor device according to item (63) further includes at least one of the inductor element and a capacitor element which are mounted in a same package as the semiconductor chip. The capacitor element smoothes a voltage received by the internal circuit.

(65) In the semiconductor device according to item (54), the first and second switch circuits, the control circuit, and the internal circuit are formed, respectively, on a plurality of semiconductor chips mounted in a same package.

(66) The semiconductor device according to item (65) further includes at least one of the inductor element and a capacitor element which are mounted in a same package as the semiconductor chips. The capacitor element smoothes a voltage received by the internal circuit.

In items (3), (13), (23), an amplifier of the control circuit outputs a voltage difference signal according to a difference between a voltage following the voltage of the third terminal and a reference voltage. A voltage pulse converter of the control circuit compares to find a magnitude relation between a voltage value of the voltage difference signal and a voltage value of an oscillation signal with a predetermined cycle, and outputs a pulse signal as a switch control signal to the first and second switches based on the magnitude relation. This can facilitate designing of the control circuit. In items (4), (14), (24), a current monitoring circuit of the control circuit outputs a current signal according to a current flowing through the inductor element. An amplifier of the control circuit outputs a voltage difference signal according to a difference between a voltage following the voltage of the third terminal and a reference voltage. A control signal generator of the control circuit fixes a switch control signal to be outputted to said first and second switches to a first logic level in response to a pulse signal with a predetermined cycle, and fixes the switch control signal to a second logic level in response to a coincidence of a voltage value of the current signal and a voltage value of the voltage difference signal. This can facilitate designing of the control circuit.

In items (5), (15), (25), a voltage comparator of the control circuit compares a voltage following the voltage of the third terminal and a reference voltage to output a voltage match signal in response to a coincidence of the two voltages. A pulse generator of the control circuit outputs a pulse signal as a switch control signal to the first and second switches in response to the voltage match signal. This can facilitate designing of the control circuit.

In items (6), (16), (26), the first and second switches of the switch circuit are controlled such that when one turns on, the other turns off.

In items (7), (17), (27), the switch circuit, the control circuit, and the internal circuit are formed on a same semiconductor chip.

In items (9), (19), (29), the switch circuit, the control circuit, and the internal circuit are formed on a plurality of semiconductor chips mounted in a same package, respectively.

In items (8), (10), (18), (20), (28), (30), at least one of the inductor element and a capacitor element smoothing a voltage received by the internal circuit is mounted in a same package in which the semiconductor chip is mounted.

In item (33), an amplifier of the control circuit outputs a voltage difference signal according to a difference between a voltage following the voltage of the fourth terminal and a reference voltage. A voltage pulse converter of the control circuit compares to find a magnitude relation between a voltage value of the voltage difference signal and a voltage value of an oscillation signal with a predetermined cycle, and based on the magnitude relation, outputs a pulse signal as a first switch control signal to the first and second switches when the voltage of the fourth terminal is lower than the input voltage, and outputs the pulse signal as a second switch control signal to the third and fourth switches when the voltage of the fourth terminal is higher than the input voltage. This can facilitate designing of the control circuit.

In item (35), a current monitoring circuit of the control circuit outputs a current signal according to a current flowing through the inductor element. An amplifier of the control circuit outputs a voltage difference signal according to a difference between a voltage following the voltage of the fourth terminal and a reference voltage. When the voltage of the fourth terminal is lower than the input voltage, a control signal generator of the control circuit fixes a first switch control signal to be outputted to the first and second switches to a first logic level in response to a pulse signal with a predetermined cycle while fixing the first switch control signal to a second logic level in response to a coincidence of a voltage value of the current signal and a voltage value of the voltage difference signal, and, when the voltage of the fourth terminal is higher than the input voltage, the control signal generator fixes a second switch control signal to be outputted to the third and fourth switches to the first logic level in response to the pulse signal and fixes the second switch control signal to the second logic level in response to a coincidence of the voltage value of the current signal and the voltage value of the voltage difference signal. This can facilitate designing of the control circuit.

In item (37), a voltage comparator of the control circuit compares a voltage following the voltage of the fourth terminal and a reference voltage and outputs a voltage match signal indicating a coincidence of the two voltages. A pulse generator of the control circuit outputs a pulse signal as a first switch control signal to the first and second switches in response to the voltage match signal when the voltage of the fourth terminal is lower than the input voltage, and the pulse generator outputs the pulse signal as a second control signal to the third to fourth switches in response to the voltage match signal when the voltage of the fourth terminal is higher than the input voltage. This can facilitate designing of the control circuit.

In items (34), (36), (38), the control circuit fixes a level of the second switch control signal in order to turn on the third switch when the voltage of the fourth terminal is lower than the input voltage, and fixes a level of the first switch control signal in order to turn on the first switch when the voltage of the fourth terminal is higher than the input voltage.

In item (39), the first and second switches of the first switch circuit are controlled such that when one turns on, the other turns off. The third and fourth switches of the second switch circuit are controlled such that when one turns on, the other turns off.

In item (46), an amplifier of the control circuit outputs a voltage difference signal according to a difference between a voltage following the voltage of the fourth terminal and a reference voltage. A voltage pulse converter of the control circuit compares to find a magnitude relation between a voltage value of the voltage difference signal and a voltage value of an oscillation signal with a predetermined cycle, and based on the magnitude relation, outputs a pulse signal as a switch control signal to the first to fourth switches. This can facilitate designing of the control circuit.

In item (47), a current monitoring circuit of the control circuit outputs a current signal according to a current flowing through the inductor element. An amplifier of the control circuit outputs a voltage difference signal according to a difference between a voltage following the voltage of the fourth terminal and a reference voltage. A control signal generator of the control circuit fixes a switch control signal to be outputted to the first to fourth switches to a first logic level in response to a pulse signal with a predetermined cycle while fixing the switch control signal to a second logic level in response to a coincidence of a voltage value of the current signal and a voltage value of the voltage difference signal. This can facilitate designing of the control circuit.

In item (48), a voltage comparator of the control circuit compares a voltage following the voltage of the fourth terminal and a reference voltage and outputs a voltage match signal indicating a coincidence of the two voltages. A pulse generator of the control circuit outputs a pulse signal as a switch control signal to the first to forth switches in response to the voltage match signal. This can facilitate designing of the control circuit.

In item (49), a pair of the first and fourth switches and a pair of the second and third switches are controlled such that one pair turns on, the other pair turns off.

In item (56), an amplifier of the control circuit alternately selects a voltage following the voltage of the fourth terminal and a voltage following the voltage of the fifth terminal, and outputs a voltage difference signal according to a difference between the selected voltage and a reference voltage. A voltage pulse converter of the control circuit compares to find a magnitude relation between a voltage value of the voltage difference signal and a voltage value of an oscillation signal with a predetermined cycle, and based on the magnitude relation, outputs a pulse signal as a first switch control signal to the first and second switches when the amplifier selects the voltage following the voltage of the fifth terminal, and outputs the pulse signal as a second switch control signal to the third and fourth switches when the amplifier selects the voltage following the voltage of the fourth terminal. This can facilitate designing of the control circuit.

In item (58), a current monitoring circuit of the control circuit outputs a current signal according to a current flowing through the inductor element. An amplifier of the control circuit alternately selects a voltage following the voltage of the fourth terminal and a voltage following the voltage of the fifth terminal and outputs a voltage difference signal according to a difference between the selected voltage and a reference voltage. When the amplifier selects the voltage following the voltage of the fifth terminal, a control signal generator of the control circuit fixes a first switch control signal to be outputted to the first and second switches to a first logic level in response to a pulse signal with a predetermined cycle while fixing the first switch control signal to a second logic level in response to a coincidence of a voltage value of the current signal and a voltage value of the voltage difference signal, and when the amplifier selects the voltage following the voltage of the fourth terminal, the control signal generator fixes a second switch control signal to be outputted to the third and fourth switches to the first logic level in response to the pulse signal while fixing the second switch control signal to the second logic level in response to a coincidence of the voltage value of the current signal and the voltage value of the voltage difference signal. This can facilitate designing of the control circuit.

In item (60), a voltage comparator of the control circuit alternately selects a voltage following the voltage of the fourth terminal and a voltage following the voltage of the fifth terminal and compares the selected voltage and a reference voltage to output a voltage match signal indicating a coincidence of the two voltages.

In response to the voltage match signal, a pulse generator of the control circuit outputs a pulse signal as a first switch control signal to the first and second switches when the voltage comparator selects the voltage following the voltage of the fifth terminal, and outputs the pulse signal as a second switch control signal to the third and fourth switches when the voltage comparator selects the voltage following the voltage of the fourth terminal. This can facilitate designing of the control circuit.

In items (57), (59), (61), the control circuit fixes a level of the second switch control signal in order to turn on the fourth switch when the voltage following the voltage of the fifth terminal is selected, while fixing a level of the first switch control signal in order to turn on the first switch when the voltage following the voltage of the fourth terminal is selected.

In item (62), the first and second switches of the first switch circuit are controlled such that when one turns on, the other turns off. The third and fourth switches of the second switch circuit are controlled such that when one turns on, the other turns off.

In items (40), (50), (63), the first and second switch circuits, the control circuit, and the internal circuit are formed on a same semiconductor chip.

In (42), (52), (65), the first and second switch circuits, the control circuit, and the internal circuit are formed on a plurality of semiconductor chips mounted in a same package, respectively.

In items (41), (43), (51), (53), (64), (66), at least one of the inductor element and a capacitor element smoothing a voltage received by the internal circuit is mounted in a same package in which the semiconductor chip is mounted.

The invention is not limited to the above embodiments and various modifications may be made without departing from the spirit and scope of the invention. Any improvement may be made in part or all of the components.

What is claimed is:

1. A semiconductor device comprising:
a first terminal receiving an input voltage;
a second terminal connected to one end of an inductor element;
a third terminal connected to the other end of the inductor element;
a switch circuit connecting said second terminal to one of said first terminal and a ground line;
a control circuit switching a connection destination of said switch circuit according to a voltage of said third terminal in order to set said third terminal at a predetermined voltage; and
an internal circuit receiving the voltage of said third terminal as a power supply voltage.

2. The semiconductor device according to claim 1, wherein
said switch circuit comprises a first switch connecting said second terminal to said first terminal, and a second switch connecting said second terminal to the ground line.

3. A semiconductor device comprising:
a first terminal receiving an input voltage;
a second terminal connected to one end of an inductor element receiving the input voltage at the other end;
a third terminal;
a switch circuit connecting said second terminal to one of said third terminal and a ground line;
a control circuit switching a connection destination of said switch circuit according to a voltage of said third terminal in order to set said third terminal at a predetermined voltage; and
an internal circuit receiving the voltage of said third terminal as a power supply voltage.

4. The semiconductor device according to claim 3, wherein
said switch circuit comprises a first switch connecting said second terminal to said third terminal, and a second switch connecting said second terminal to the ground line.

5. A semiconductor device comprising:
a first terminal receiving an input voltage;
a second terminal connected to a ground line via an inductor element;
a third terminal;
a switch circuit connecting said second terminal to one of said first terminal and said third terminal;
a control circuit switching a connection destination of said switch circuit according to a voltage of said third terminal in order to set said third terminal at a predetermined voltage; and
an internal circuit receiving the voltage of said third terminal as a power supply voltage.

6. The semiconductor device according to claim 5, wherein
said switch circuit comprises a first switch connecting said second terminal to said first terminal, and a second switch connecting said second terminal to said third terminal.

7. A semiconductor device comprising:
a first terminal receiving an input voltage;
a second terminal connected to one end of an inductor element;
a third terminal connected to the other end of the inductor element;
a fourth terminal;
a first switch circuit connecting said second terminal to one of said first terminal and a ground line;
a second switch circuit connecting said third terminal to one of said fourth terminal and the ground line;
a control circuit which, in order to set said fourth terminal at a predetermined voltage, selects one of said first and second switch circuits according to a magnitude relation between a voltage of said fourth terminal and the input voltage, and switches a connection destination of the selected switch circuit according to the voltage of said fourth terminal while fixing a connection destination of an unselected switch circuit to a side that is not a ground line side; and
an internal circuit receiving the voltage of said fourth terminal as a power supply voltage.

8. The semiconductor device according to claim 7, wherein:
said first switch circuit comprises a first switch connecting said second terminal to said first terminal, and a second switch connecting said second terminal to the ground line; and
said second switch circuit comprises a third switch connecting said third terminal to said fourth terminal, and a fourth switch connecting said third terminal to the ground line.

9. A semiconductor device comprising:
a first terminal receiving an input voltage;
a second terminal connected to one end of an inductor element;
a third terminal connected to the other end of the inductor element;
a fourth terminal;
a first switch circuit connecting said second terminal to one of said first terminal and a ground line;
a second switch circuit connecting said third terminal to one of said fourth terminal and the ground line;
a control circuit fixing a connection destination of one of said first and second switch circuits to the ground line and fixing a connection destination of the other of said first and second switch circuits to a side that is not a ground line side according to a voltage of said fourth terminal in order to set said fourth terminal at a predetermined voltage; and
an internal circuit receiving the voltage of said fourth terminal as a power supply voltage.

10. The semiconductor device according to claim 9, wherein:
said first switch circuit comprises a first switch connecting said second terminal to said first terminal, and a second switch connecting said second terminal to the ground line; and
said second switch circuit comprises a third switch connecting said third terminal to said fourth terminal, and a fourth switch connecting said third terminal to the ground line.

11. A semiconductor device comprising:
a first terminal receiving an input voltage;
a second terminal connected to one end of an inductor element;
a third terminal connected to the other end of the inductor element;
a fourth terminal;
a fifth terminal;
a first switch circuit connecting said second terminal to one of said first and fifth terminals;
a second switch circuit connecting said third terminal to one of said fourth terminal and a ground line;
a control circuit alternately performing an operation of switching a connection destination of said second switch circuit according to a voltage of said fourth terminal in order to set said fourth terminal at a first predetermined voltage and an operation of switching a connection destination of said first switch circuit according to a voltage of said fifth terminal in order to set said fifth terminal at a second predetermined voltage; and
an internal circuit receiving at least one of the voltages of said fourth terminal and of said fifth terminal as a power supply voltage.

12. The semiconductor device according to claim 11, wherein:
said first switch circuit comprises a first switch connecting said second terminal to said first terminal, and a second switch connecting said second terminal to said fifth terminal; and
said second switch circuit comprises a third switch connecting said third terminal to said fourth terminal, and a fourth switch connecting said third terminal to the ground line.

13. A printed-circuit board comprising a semiconductor device mounted thereon, the semiconductor device including:
a first terminal receiving an input voltage;
a second terminal connected to one end of an inductor element;
a third terminal connected to the other end of the inductor element;
a switch circuit connecting said second terminal to one of said first terminal and a ground line;
a control circuit switching a connection destination of said switch circuit according to a voltage of said third terminal in order to set said third terminal at a predetermined voltage; and
an internal circuit receiving the voltage of said third terminal as a power supply voltage.

14. A printed-circuit board comprising a semiconductor device mounted thereon, the semiconductor device including:
a first terminal receiving an input voltage;
a second terminal connected to one end of an inductor element receiving the input voltage at the other end;
a third terminal;
a switch circuit connecting said second terminal to one of said third terminal and a ground line;
a control circuit switching a connection destination of said switch circuit according to a voltage of said third terminal in order to set said third terminal at a predetermined voltage; and
an internal circuit receiving the voltage of said third terminal as a power supply voltage.

15. A printed-circuit board comprising a semiconductor device mounted thereon, the semiconductor device including:
a first terminal receiving an input voltage;
a second terminal connected to a ground line via an inductor element;
a third terminal;
a switch circuit connecting said second terminal to one of said first terminal and said third terminal;
a control circuit switching a connection destination of said switch circuit according to a voltage of said third terminal in order to set said third terminal at a predetermined voltage; and
an internal circuit receiving the voltage of said third terminal as a power supply voltage.

16. A printed-circuit board comprising a semiconductor device mounted thereon, the semiconductor device including:
a first terminal receiving an input voltage;
a second terminal connected to one end of an inductor element;
a third terminal connected to the other end of the inductor element;
a fourth terminal;
a first switch circuit connecting said second terminal to one of said first terminal and a ground line;
a second switch circuit connecting said third terminal to one of said fourth terminal and the ground line;
a control circuit which, in order to set said fourth terminal at a predetermined voltage, selects one of said first and second switch circuits according to a magnitude relation between a voltage of said fourth terminal and the input voltage, and switches a connection destination of the selected switch according to a voltage of said fourth terminal while fixing a connection destination of an unselected switch to a side that is not a ground line side; and
an internal circuit receiving the voltage of said fourth terminal as a power supply voltage.

17. A printed-circuit board comprising a semiconductor device mounted thereon, the semiconductor device including:
a first terminal receiving an input voltage;
a second terminal connected to one end of an inductor element;
a third terminal connected to the other end of the inductor element;
a fourth terminal;
a first switch circuit connecting said second terminal to one of said first terminal and a ground line;
a second switch circuit connecting said third terminal to one of said fourth terminal and the ground line;
a control circuit fixing a connection destination of one of said first and second switch circuits to the ground line and fixing a connection destination of the other of said first and second switch circuits to a side that is not a ground line side according to a voltage of said fourth terminal in order to set said fourth terminal at a predetermined voltage; and
an internal circuit receiving the voltage of said fourth terminal as a power supply voltage.

18. A printed-circuit board comprising a semiconductor device mounted thereon, the semiconductor device including:
a first terminal receiving an input voltage;
a second terminal connected to one end of an inductor element;
a third terminal connected to the other end of the inductor element;
a fourth terminal;
a fifth terminal;
a first switch circuit connecting said second terminal to one of said first and fifth terminals;
a second switch circuit connecting said third terminal to one of said fourth terminal and a ground line;
a control circuit alternately performing an operation of switching a connection destination of said second switch circuit according to a voltage of said fourth terminal in order to set said fourth terminal at a first predetermined voltage and an operation of switching a connection destination of said first switch circuit according to a voltage of said fifth terminal in order to set said fifth terminal at a second predetermined voltage; and
an internal circuit receiving at least one of the voltages of said fourth terminal and of said fifth terminal as a power supply voltage.

19. An electronics device comprising a semiconductor device, the semiconductor device including:
a first terminal receiving an input voltage;
a second terminal connected to one end of an inductor element;
a third terminal connected to the other end of the inductor element;
a switch circuit connecting said second terminal to one of said first terminal and a ground line;
a control circuit switching a connection destination of said switch circuit according to a voltage of said third terminal in order to set said third terminal at a predetermined voltage; and
an internal circuit receiving the voltage of said third terminal as a power supply voltage.

20. An electronics device comprising a semiconductor device, the semiconductor device including:
a first terminal receiving an input voltage;
a second terminal connected to one end of an inductor element receiving the input voltage at the other end;
a third terminal;
a switch circuit connecting said second terminal to one of said third terminal and a ground line;
a control circuit switching a connection destination of said switch circuit according to a voltage of said third terminal in order to set said third terminal at a predetermined voltage; and
an internal circuit receiving the voltage of said third terminal as a power supply voltage.

21. An electronics device comprising a semiconductor device, the semiconductor device including:
a first terminal receiving an input voltage;
a second terminal connected to a ground line via an inductor element;
a third terminal;
a switch circuit connecting said second terminal to one of said first terminal and said third terminal;
a control circuit switching a connection destination of said switch circuit according to a voltage of said third terminal in order to set said third terminal at a predetermined voltage; and
an internal circuit receiving the voltage of said third terminal as a power supply voltage.

22. An electronics device comprising a semiconductor device, the semiconductor device including:
a first terminal receiving an input voltage;
a second terminal connected to one end of an inductor element;
a third terminal connected to the other end of the inductor element;
a fourth terminal;
a first switch circuit connecting said second terminal to one of said first terminal and a ground line;
a second switch circuit connecting said third terminal to one of said fourth terminal and the ground line;
a control circuit which, in order to set said fourth terminal at a predetermined voltage, selects one of said first and second switch circuits according to a magnitude relation between a voltage of said fourth terminal and the input voltage, and switches a connection destination of the selected switch according to a voltage of said fourth terminal while fixing a connection destination of an unselected switch to a side that is not a ground line side; and
an internal circuit receiving the voltage of said fourth terminal as a power supply voltage.

23. An electronics device comprising a semiconductor device, the semiconductor device including:
a first terminal receiving an input voltage;
a second terminal connected to one end of an inductor element;
a third terminal connected to the other end of the inductor element;
a fourth terminal;
a first switch circuit connecting said second terminal to one of said first terminal and a ground line;
a second switch circuit connecting said third terminal to one of said fourth terminal and the ground line;
a control circuit fixing a connection destination of one of said first and second switch circuits to the ground line and fixing a connection destination of the other of said first and second switch circuits to a side that is not a ground line side according to a voltage of said fourth terminal in order to set said fourth terminal at a predetermined voltage; and
an internal circuit receiving the voltage of said fourth terminal as a power supply voltage.

24. An electronics device comprising a semiconductor device, the semiconductor device including:
a first terminal receiving an input voltage;
a second terminal connected to one end of an inductor element;
a third terminal connected to the other end of the inductor element;
a fourth terminal;
a fifth terminal;
a first switch circuit connecting said second terminal to one of said first and fifth terminals;
a second switch circuit connecting said third terminal to one of said fourth terminal and a ground line;
a control circuit alternately performing an operation of switching a connection destination of said second switch circuit according to a voltage of said fourth terminal in order to set said fourth terminal at a first predetermined voltage and an operation of switching a connection destination of said first switch circuit according to a voltage of said fifth terminal in order to set said fifth terminal at a second predetermined voltage; and
an internal circuit receiving at least one of the voltages of said fourth terminal and of said fifth terminal as a power supply voltage.
